(19) United States
(12) Patent Application Publication
(10) Pub. No.: US 2023/0009165 A1
(43) Pub. Date: Jan. 12, 2023

(54) WIRELESS OCCUPANCY SENSORS AND METHODS FOR USING THE SAME

(71) Applicant: Sidewalk Labs LLC, New York, NY (US)

(72) Inventors: Nick Jonas, New York, NY (US); Louisa Sainz de la Maza, New York, NY (US); Thomas Kennedy, San Deigo, CA (US); Noah Greenbaum, New York, NY (US); Prem Ramaswami, New York, NY (US); William Cowles, Brooklyn, NY (US)

(21) Appl. No.: 17/369,397

(22) Filed: Jul. 7, 2021

(51) Int. Cl. G01S 13/10; G01S 17/10; G01R 33/02; G01S 7/481; G08G 1/14; H01Q 1/36

(52) U.S. Cl. CPC G01S 13/10; G01S 17/10; G01R 33/02; G01S 7/4813; G08G 1/142; H01Q 1/362

(57) ABSTRACT

Wireless occupancy sensors and methods for using the same are provided. In some embodiments, a occupancy sensor comprises: a housing that includes a window positioned at a top portion of the housing; a battery at a lower portion of the housing; a first magnetometer that detects changes in a magnetic field when a vehicle moves over the first magnetometer; an optical sensor that detects one or more objects in a field of view of the optical sensor through the window; a transmitter for transmitting sensor data to a gateway device, and a processor that controls the first magnetometer, the optical sensor, and the transmitter.

### TECHNICAL FIELD

The disclosed subject matter relates to wireless occupancy sensors and methods for using the same. More particularly, the disclosed subject matter relates to wireless occupancy sensors that can be used to provide privacy-sensitive methods, systems, and media for detecting the presence of a vehicle and generating and/or presenting real-time parking information.

### BACKGROUND

Vehicle drivers frequently spend a lot of time searching for parking spaces. For example, this search for parking spaces can include searching for on-street parking at a curb, which wastes time, creates congestion, unnecessarily consumes fuel or battery life, and/or creates vehicle emissions as such drivers continuously search for the perfect space at or near their destination. In another example, this search for parking spaces can include searching for off-street parking in a parking garage or a parking lot, which occupies valuable real estate that might otherwise be used to provide additional housing options. In some instances, the need for a parking garage or a parking lot may contribute to higher rent demands.

A driver may want to access a map or list of available parking spots in a particular location. However, this can be difficult to collate. Moreover, many cities are working toward a future with much less parking than is typically available today.

Although parking sensor devices have been developed in an attempt to solve these problems, such parking sensor devices tend to be overly expensive, unnecessarily invasive, and easily broken.

Accordingly, it is desirable to provide new wireless occupancy sensors and methods for using the same.

### SUMMARY

Wireless occupancy sensors and methods for using the same are provided.

In accordance with some embodiments of the disclosed subject matter, an occupancy sensor is provided, the occupancy sensor comprising: a housing that includes a window positioned at a top portion of the housing; a battery at a lower portion of the housing; a first magnetometer that detects changes in a magnetic field when a vehicle moves over the first magnetometer; an optical sensor that detects one or more objects in a field of view of the optical sensor through the window; a transmitter for transmitting sensor data to a gateway device, and a processor that controls the first magnetometer, the optical sensor, and the transmitter.

In some embodiments, the housing includes a first set of exterior threads on a body portion of the housing that match a second set of interior threads on a socket configured to be positioned within an opening of a surface.

In some embodiments, the first magnetometer is a low-power magnetometer, and wherein the optical sensor is woken in response to the first magnetometer detecting a change in a magnetic field.

In some embodiments, the occupancy sensor further comprises a second magnetometer.

In some embodiments, the optical sensor is an infrared sensor. In some embodiments, the optical sensor is a time-of-flight sensor.

In some embodiments, the transmitter and the processor are mounted on a first printed circuit board and the time-of-flight sensor is mounted on a second printed circuit board that is separate from the first printed circuit board and wherein the second printed circuit board mounted at the top portion of the housing. In some embodiments, the occupancy sensor further comprises a cable that connects the second printed circuit board to the first printed circuit board. In some embodiments, the optical sensor is a pulse doppler radar sensor. In some embodiments, the optical sensor is an infrared pulse doppler radar sensor.

In some embodiments, the transmitter is a wireless transmitter and further comprising an antenna coupled to an output of the transmitter.

In some embodiments, the antenna is a helical-shaped antenna that extends vertically through a body portion of the housing.

In some embodiments, the transmitter is configured to transmit sensor data over a 915 MHz radio protocol to a gateway device.

In some embodiments, the occupancy sensor further comprises a humidity sensor to indicate whether water has leaked into the occupancy sensor.

In some embodiments, the occupancy sensor further comprises a feedback indicator. In some embodiments, the feedback indicator is a light emitting diode.

In some embodiments, the housing includes at least one protrusion on an exterior surface of a body portion of the housing that is configured to engage with a socket under the pressure of a spring.

In some embodiments, the occupancy sensor further comprises an actuator that is configured to change a position of the occupancy sensor within a socket. In some embodiments, the occupancy sensor further comprises a gasket configured to seal an interior space of a socket when the occupancy sensor is fully inserted into the socket.

In accordance with some embodiments of the disclosed subject matter, a tool for installing occupancy sensor devices is provided, the tool comprising: a cylindrical body having a first diameter and having a first set of exterior threads that complement a second set of interior threads of an assembly for inserting an occupancy sensor device; a cover portion that is formed on the cylindrical body, wherein the cover portion has a second diameter that is greater than the first diameter of the cylindrical body; and a handle portion that is formed on the cover portion, wherein the handle portion is configured to allow the tool to be separated from the assembly for inserting the occupancy sensor device.

In some embodiments, the cover portion is configured to align the assembly for inserting the occupancy sensor device with a surface of a pavement.

In some embodiments, the cover portion is configured to position the assembly at a particular depth within an opening formed in a pavement.

In some embodiments, the particular depth of the assembly causes a top surface of the occupancy sensor device to be at a level position in comparison with a surface of the pavement.

In some embodiments, the particular depth of the assembly causes a top surface of the occupancy sensor device to be at a higher position in comparison with a surface of the pavement.

In some embodiments, the first set of exterior threads are formed on a portion of the cylindrical body.

In some embodiments, the cover portion includes a plurality of holes.

In some embodiments, the cover portion includes a plurality of overflow holes that are positioned on the cover portion based on dimensions of an opening in the pavement.

In accordance with some embodiments of the disclosed subject matter, a method for installing occupancy sensors is provided, the method comprising: forming an opening within a pavement; inserting a cap assembly into the opening of the pavement, wherein the cap assembly is capable of receiving an occupancy sensor device; positioning the occupancy sensor device within the cap assembly, wherein the occupancy sensor device comprises a housing that complements the positioning of the occupancy sensor device within the cap assembly, and wherein the housing encloses a battery that provides power to the occupancy sensor device and a printed circuit board substrate, the printed circuit board substrate including electronic circuitry, the electronic circuitry configured to detect whether a vehicle is positioned over the occupancy sensor device, the electronic circuitry including a plurality of integrated circuits coupled to the printed circuit board substrate, and the plurality of integrated circuits including (i) a magnetometer that detects changes in a magnetic field when a vehicle moves over the magnetometer, (ii) an optical sensor that detects one or more objects in a field of view of the optical sensor through a window positioned at a top portion of the housing, (iii) a wireless communication chip for transmitting sensor data to a gateway device; and (iv) a microcontroller that controls the magnetometer, the optical sensor, and the wireless communication chip; and activating the occupancy sensor device.

In some embodiments, the methods further comprise drilling into the pavement to create the opening of the pavement.

In some embodiments, the opening formed in the pavement is a cylindrical opening that is less than about 50 millimeters in depth and less than about 50 millimeters in diameter.

In some embodiments, the methods further comprise providing an adhesive in the opening of the pavement, wherein the adhesive causes the cap assembly to be at a fixed position within the opening after allowing the adhesive to cure.

In some embodiments, the cap assembly is inserted into the opening of the pavement using a removable installation tool that aligns the cap assembly with a surface of the pavement.

In some embodiments, the cap assembly has a first set of interior threads and wherein the removable installation tool has a second set of exterior threads that complement the first set of interior threads of the cap assembly.

In some embodiments, the removable installation tool causes the cap assembly to be at a particular depth from the surface of the opening.

In some embodiments, the cap assembly has a first set of interior threads, wherein the housing of the occupancy sensor has a second set of exterior threads that complement the first set of interior threads of the cap assembly, and wherein the occupancy sensor device is positioned within the cap assembly by using the second set of exterior threads to thread the occupancy sensor into the first set of interior threads of the cap assembly.

In some embodiments, the occupancy sensor device is activated using a magnetometer tool.

In some embodiments, the housing of the occupancy sensor device has a beveled edge and wherein, upon positioning the occupancy sensor device within the cap assembly, the beveled edge creates a gap between a surface of the pavement and the occupancy sensor device.

In some embodiments, the method further comprises applying a sealing component into the gap between the surface of the pavement and the occupancy sensor device.

In some embodiments, the sealing component is a low viscosity rubber. In some embodiments, upon positioning the occupancy sensor device within the cap assembly, a top surface of the occupancy sensor device is at a level position in comparison with a surface of the pavement.

In some embodiments, upon positioning the occupancy sensor device within the cap assembly, a top surface of the occupancy sensor device is at a higher position in comparison with a surface of the pavement.

In some embodiments, the occupancy sensor device includes a spring component that allows the occupancy sensor device to be positioned within the cap assembly such that the top surface of the occupancy sensor device is changed from the higher position to a level position in comparison with the surface of the pavement.

In some embodiments, the cap assembly has a first set of interior threads, wherein the housing of the occupancy sensor has a spring component and a second set of exterior threads that complement the first set of interior threads of the cap assembly, wherein the occupancy sensor device is positioned within the cap assembly by using the second set of exterior threads to thread the occupancy sensor into the first set of interior threads of the cap assembly, and wherein, upon removing the second set of exterior threads from the first set of interior threads of the cap assembly, the spring component changes a position of the occupancy sensor device such that the top surface of the occupancy sensor device is changed from being at a level position in comparison with the surface of the pavement to a higher position.

In some embodiments, the occupancy sensor device includes an actuator that is configured to change a position of the occupancy sensor device within the cap assembly.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIGS. 1A and 1B show example schematic diagrams for use of vehicle sensors in accordance with some embodiments of the disclosed subject matter.

FIG. 2 shows a detailed example of hardware that can be used in a vehicle sensor in accordance with some embodiments of the disclosed subject matter.

FIG. 3 shows an illustrative example of a process for generating and presenting parking information using one or more vehicle sensors in accordance with some embodiments of the disclosed subject matter.

FIGS. 4A and 4B show example user interfaces for presenting parking information based on data from one or more vehicle sensors in accordance with some embodiments of the disclosed subject matter.

FIGS. 5A, 5B, 5C, and 5D show example user interfaces for presenting data related to parking information based on data from one or more vehicle sensors in accordance with some embodiments of the disclosed subject matter.

FIG. 6 shows a detailed example of hardware that can be used in a gateway device, a server, and/or a user device in accordance with some embodiments of the disclosed subject matter.

FIG. 7 shows an illustrative example of a measurement routine used in a vehicle sensor in accordance with some embodiments of the disclosed subject matter.

FIGS. 8A and 8B show detailed examples of hardware that can be used in a vehicle sensor in accordance with some embodiments of the disclosed subject matter.

FIG. 8C shows an example of an assembled vehicle sensor in accordance with some embodiments of the disclosed subject matter.

FIG. 9A shows a detailed example of hardware that can be used in a vehicle sensor in accordance with some embodiments of the disclosed subject matter.

FIG. 9B shows an example of an assembled vehicle sensor in accordance with some embodiments of the disclosed subject matter.

FIG. 10 shows an illustrative example of a process for installing a vehicle sensor in accordance with some embodiments of the disclosed subject matter.

FIG. 11 shows an example of hardware that can be used for installing a vehicle sensor in accordance with some embodiments of the disclosed subject matter.

FIG. 12 shows a detailed example of a vehicle sensor installation-in-progress in accordance with some embodiments of the disclosed subject matter.

FIGS. 13A and 13B show example illustrations of hardware installation of a vehicle sensor in accordance with some embodiments of the disclosed subject matter.

FIGS. 14A, 14B, and 14C show examples of completed in-ground vehicle sensor installation in accordance with some embodiments of the disclosed subject matter.

### DETAILED DESCRIPTION

In accordance with various embodiments, wireless occupancy sensors and methods for using the same are provided. In some embodiments, wireless occupancy sensors can be used to provide privacy-sensitive mechanisms (which can include methods, systems, and media) for detecting the presence of a vehicle and generating and/or presenting real-time parking information.

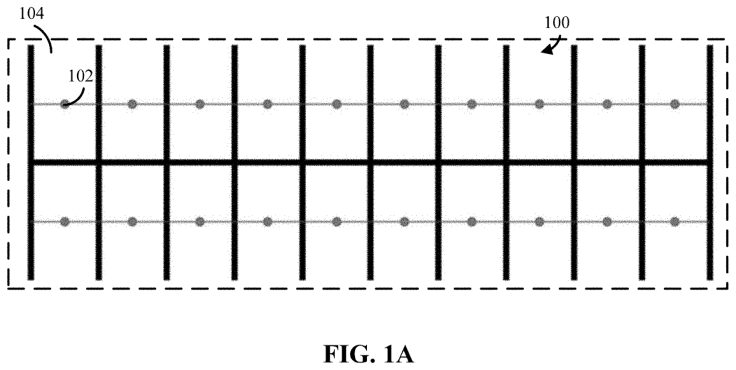

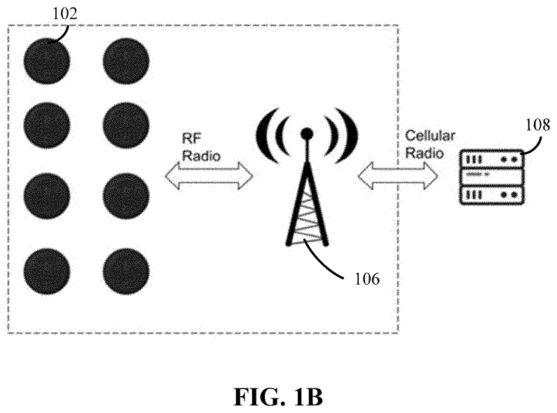

In some embodiments, the mechanisms described herein can include vehicle sensors that can determine whether a vehicle (e.g., a car, a truck, a motorcycle, etc.) is positioned over the vehicle sensor. In some embodiments, as described below in connection with FIGS. 1A, 2, and 7, the vehicle sensor can include a magnetometer, which can detect changes in a magnetic field when a vehicle moves over the magnetometer. In some embodiments, a change in the magnetic field detected by the magnetometer can trigger an optical sensor that detects optical light reflected from an optical light source. In some embodiments, the amount of reflected light can be used to determine that a vehicle is positioned over the vehicle sensor. In some embodiments, a vehicle sensor can be positioned at any suitable location, such as in the surface of a parking spot, and/or in any other suitable location, as shown in and described below in connection with FIG. 1A. In some embodiments, each parking spot in a parking lot or garage can have a vehicle sensor placed in the spot.

In some embodiments, data from the vehicle sensor can be stored in any suitable manner. For example, in some embodiments, a group of vehicle sensors can each transmit (e.g., via a radio frequency link, and/or in any other suitable manner) sensor data to a gateway device. In some such embodiments, the gateway device can be located at any suitable location. For example, in some embodiments, the gateway device can be located in a parking lot and can receive data from all of the vehicle sensors located in the parking lot. In some embodiments, the gateway device can then transmit (e.g., via cellular uplink, and/or in any other suitable manner) the data to a server that collects parking information from multiple parking lots or garages.

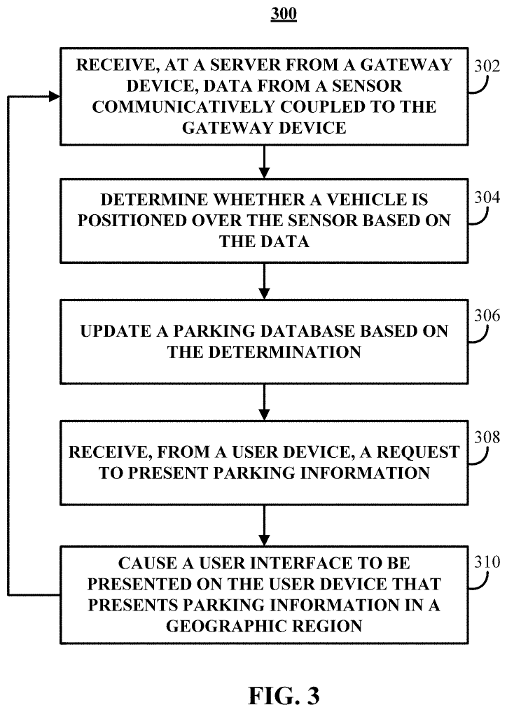

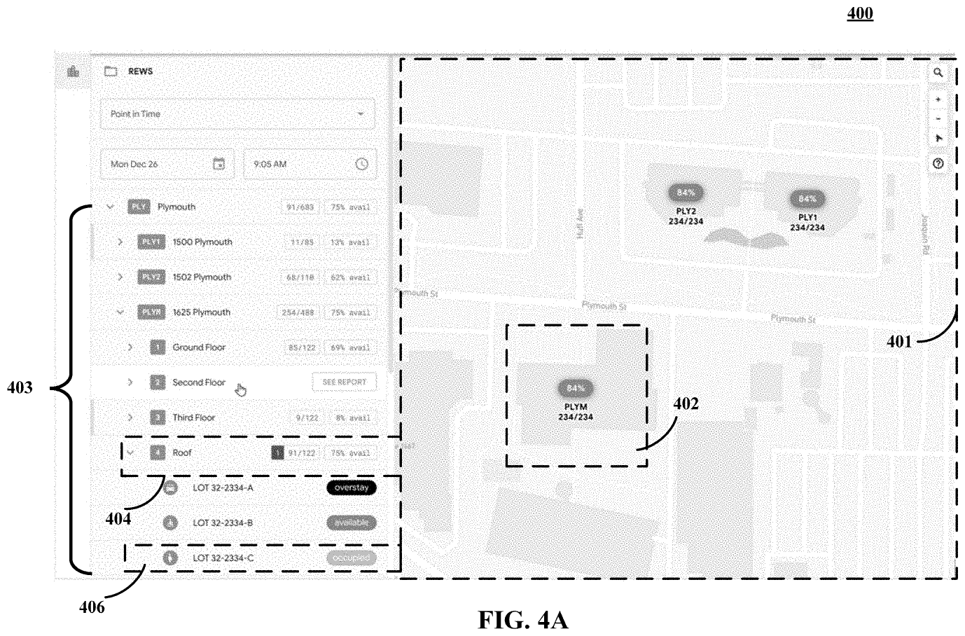

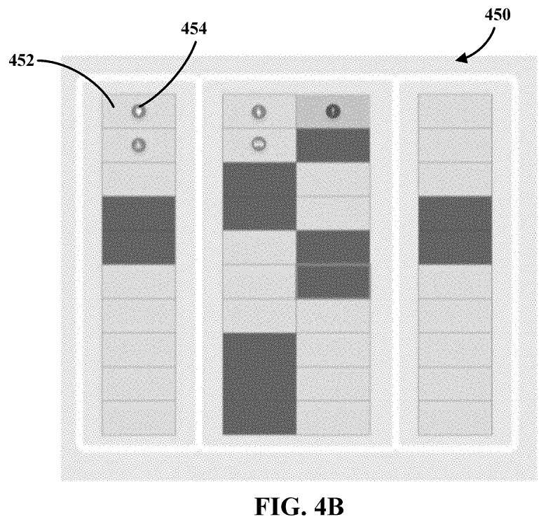

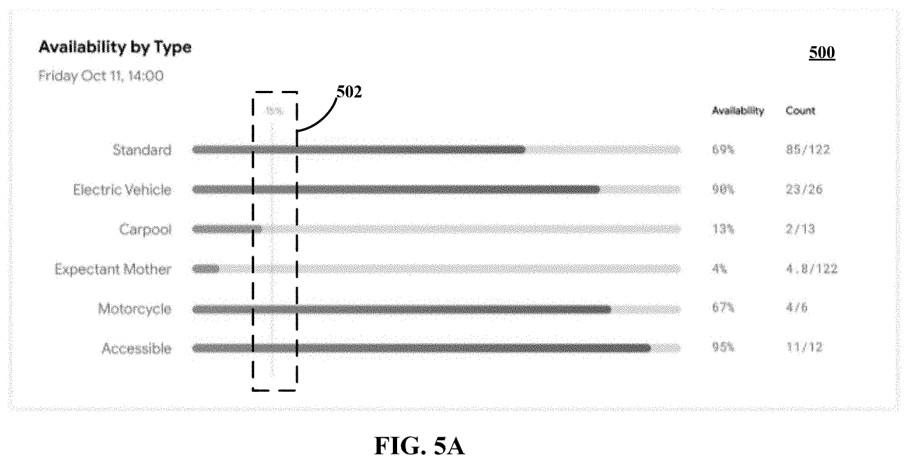

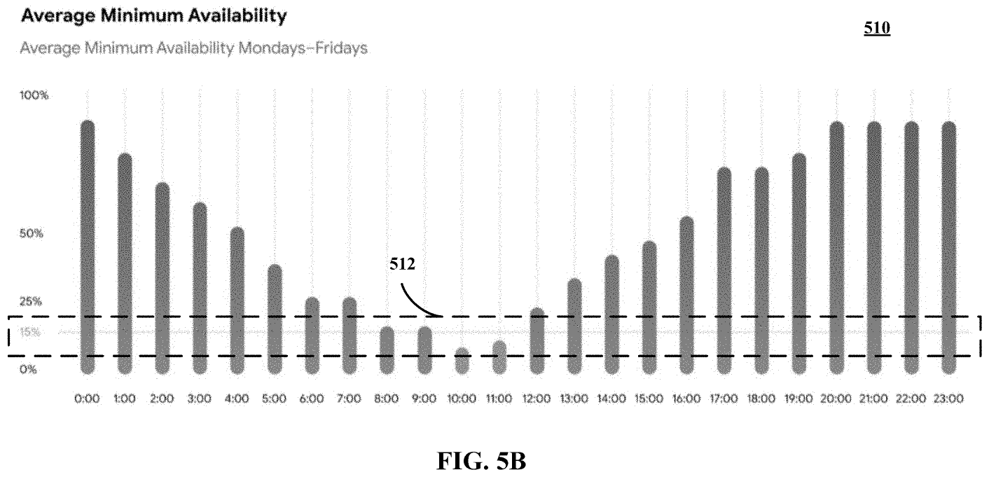

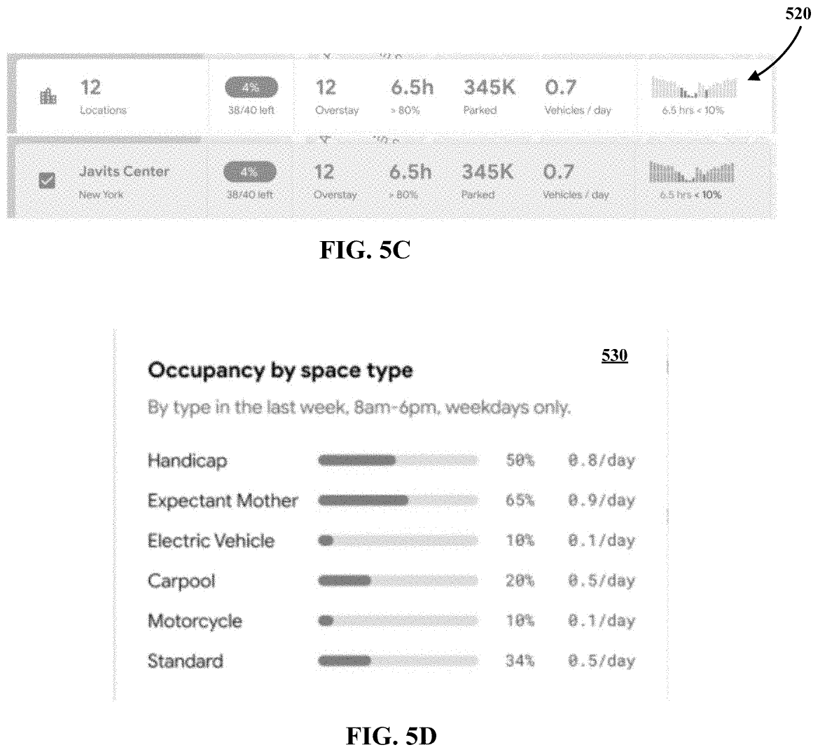

In some embodiments, as described below in connection with FIG. 3, the server can present any suitable parking information based on the received data from the vehicle sensors. For example, in some embodiments, the server can generate user interfaces that indicate currently available parking spots in a particular parking lot or garage, as shown in and described below in connection with FIGS. 4A and 4B. As another example, in some embodiments, the server can generate user interfaces (e.g., as shown in FIGS. 5A, 5B, 5C, and/or 5D) that can be used to analyze usage of a parking lot or garage by any suitable entity, such as an administrator of a parking lot or gate, an urban planner, and/or any other suitable entity.

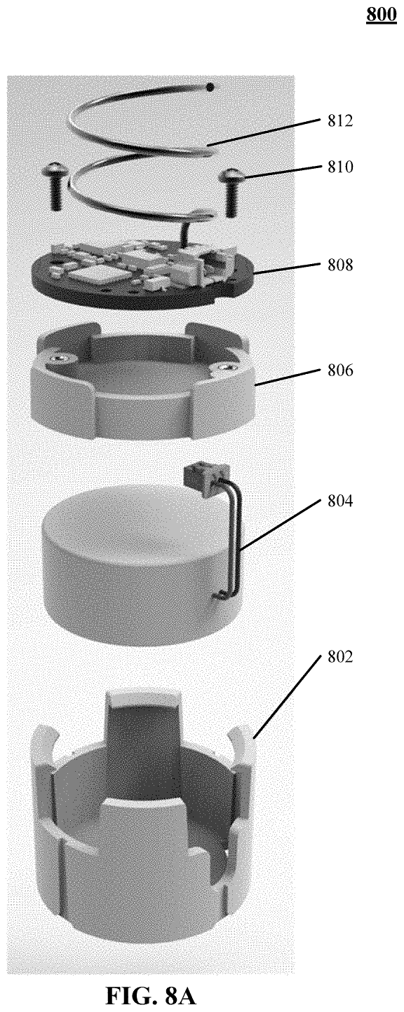

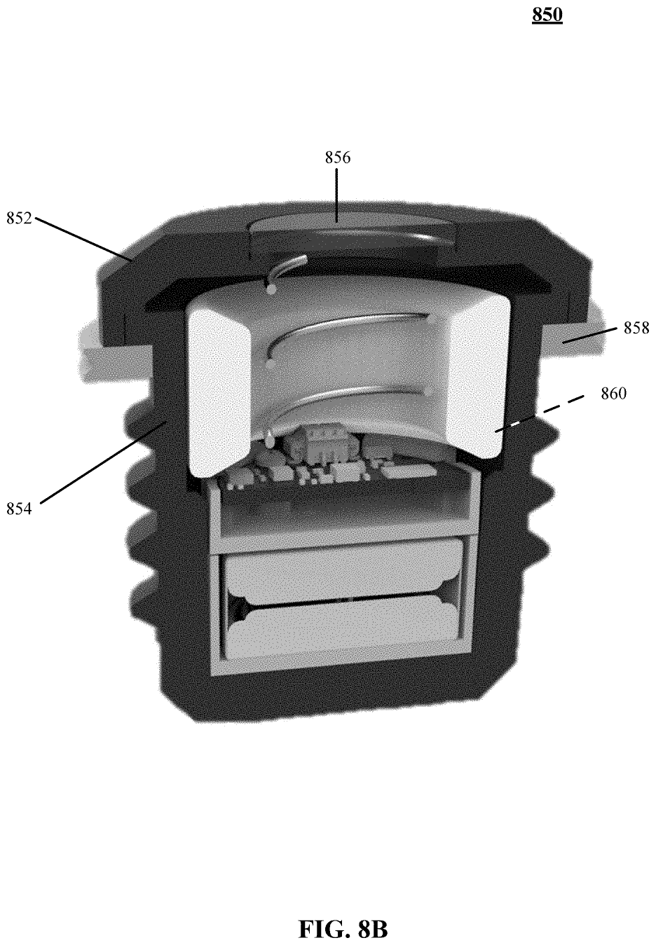

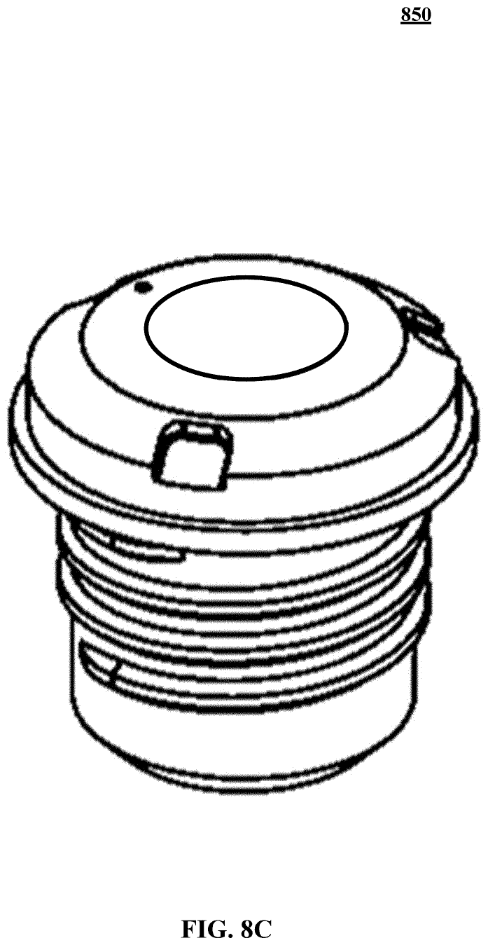

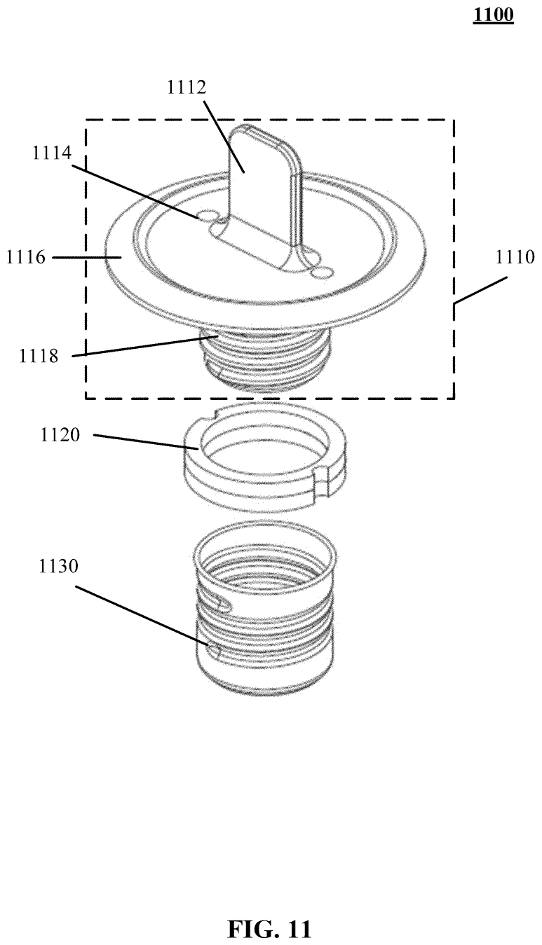

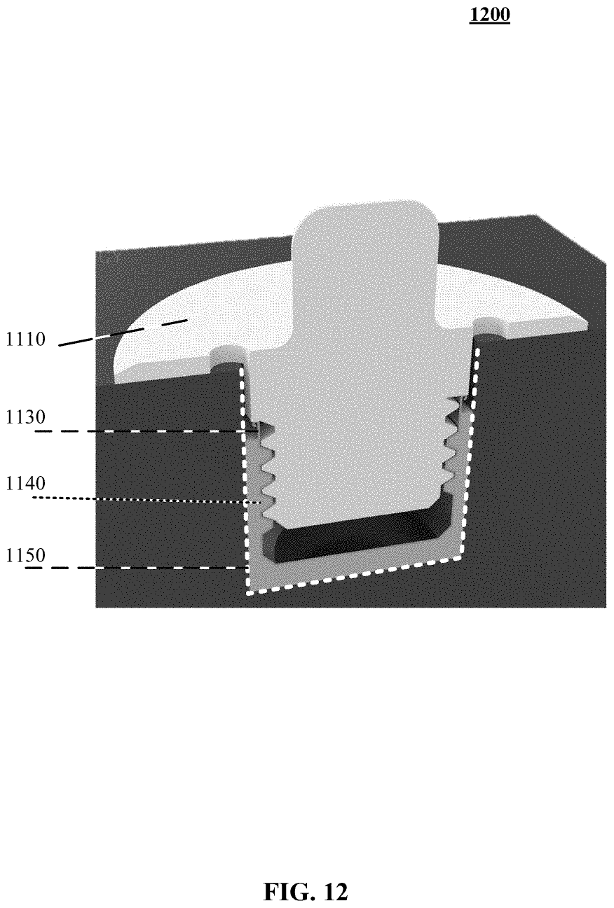

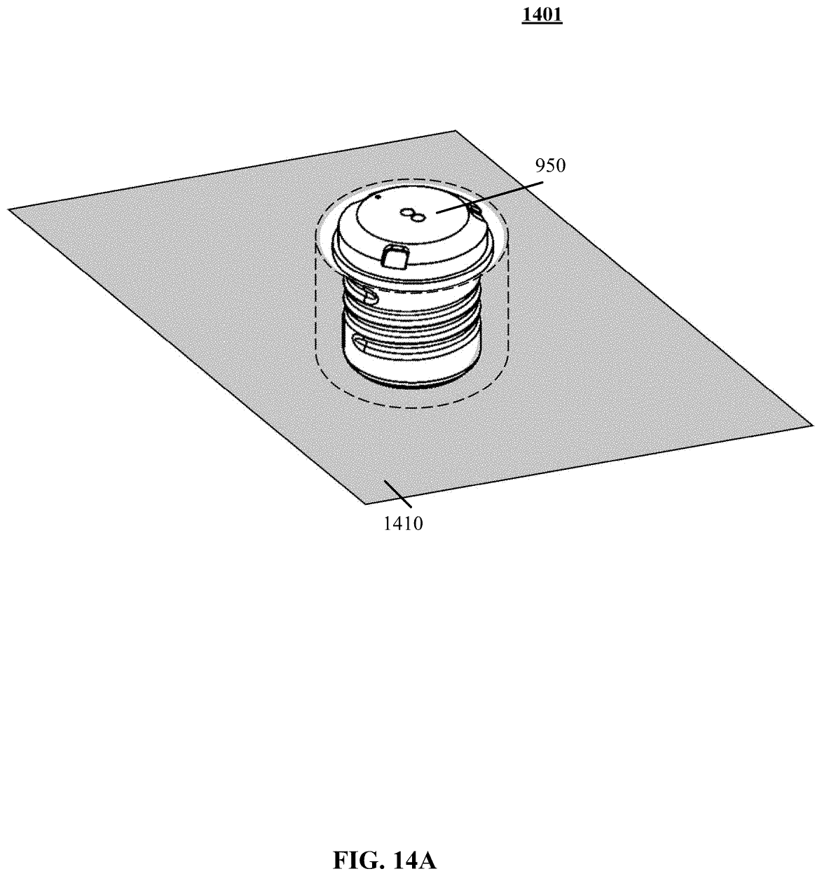

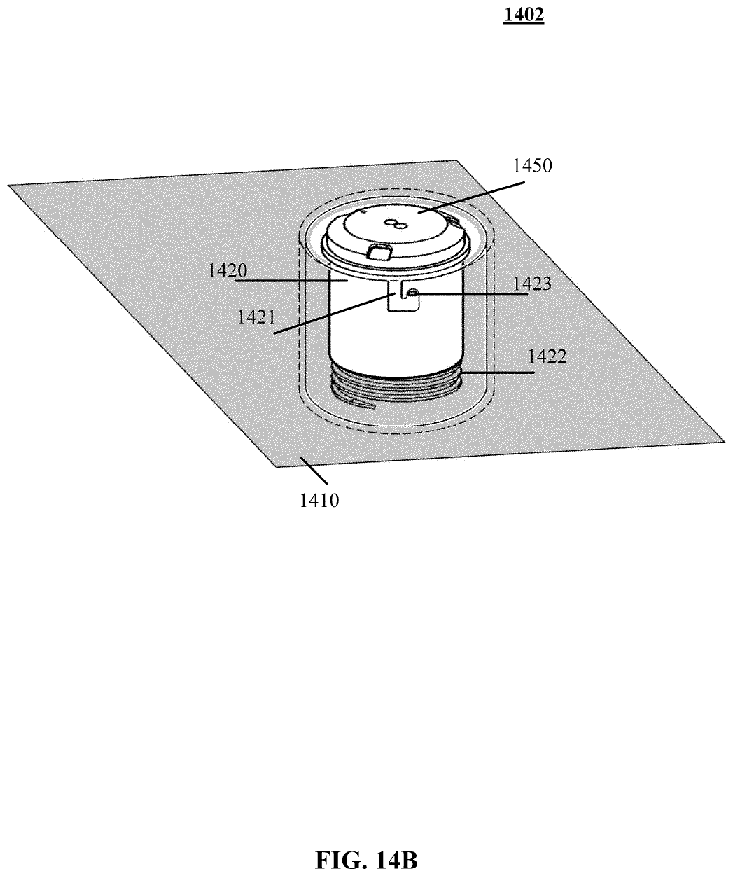

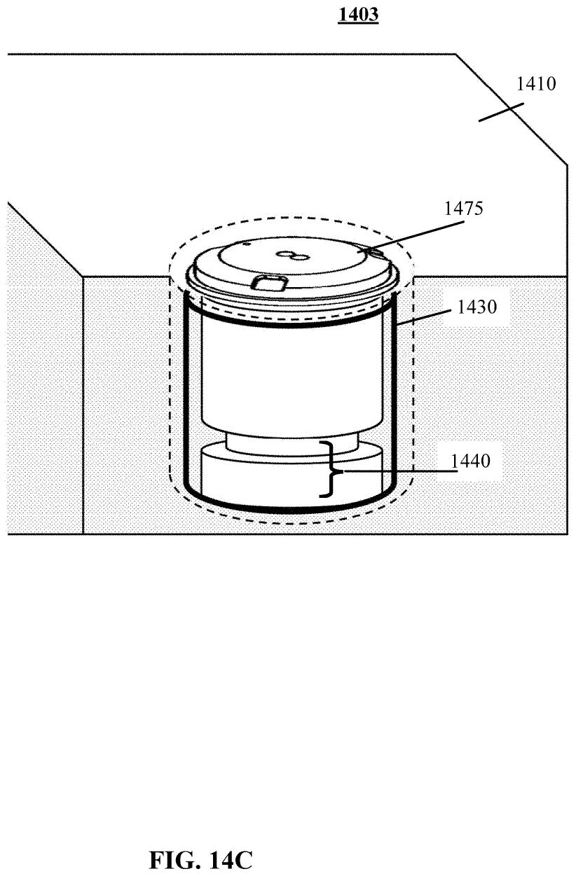

In some embodiments, as shown in and described below in connection with FIGS. 8B, 10, and 12, the vehicle sensor can be constructed for rugged applications and installed within the ground. For example, in some embodiments, the vehicle sensor housing can be airtight, and/or otherwise suitably insulated from weather conditions. In some embodiments, the vehicle sensor can be mounted in a socket which has been installed below the parking lot surface. For example, in some embodiments, a final vertical alignment of the vehicle sensor can be determined by placement of the socket as shown in FIGS. 11 and 12. As another example, in some embodiments, the vertical alignment of the vehicle sensor (e.g., as shown in FIG. 14) can place the vehicle sensor out of reach for snowplows, street sweepers, and/or any other suitable road maintenance vehicles.

It should be noted that the wireless occupancy sensors described herein can be used in any suitable application. For example, although the embodiments described herein generally describe the wireless occupancy sensors as parking sensors to determine whether a vehicle is currently parked in a particular spot, this is merely illustrative. The wireless occupancy sensors can be used to detect the number of vehicles that are currently parked in a parking lot and can be used to dynamically set prices for parking in the parking lot based on current availability (e.g., such that the price is relatively lower in instances in which the current availability is greater than a predetermined availability threshold and such that the price is relatively higher in instances in which the current availability is below a predetermined availability threshold). In another example, the wireless occupancy sensors can be configured at a traffic intersection to control a traffic light. In yet another example, the wireless occupancy sensors can be used to dynamically route vehicles to curbside parking or drop off spots (e.g., upon detecting the parking area as being available, the parking area can be reserved for a vehicle that is making a delivery, picking up or dropping off a passenger, etc.). In continuing this example, such a vehicle can receive dynamic directions to a currently available parking spot based on current occupancy as detected by the wireless occupancy sensors.

These and other features of the wireless occupancy sensors are further described in connection with FIGS. 1A-14C.

Turning to FIG. 1A, a schematic diagram that illustrates placements of vehicle sensors in accordance with some embodiments of the disclosed subject matter is shown. As illustrated, a parking lot 100 can include a group of parking spaces, such as a parking space 104. Note that, in some embodiments, parking lot 100 can be any suitable type of parking lot or garage, such as an open-air parking lot, a covered parking garage, a parking garage with multiple levels, and/or any other suitable type of lot or garage. Additionally, note that, although parking lot 100 is shown in FIG. 1A as having parking spaces arranged in a grid, in some embodiments, the parking spaces can be arranged in any suitable shape or orientation, such as in a line. Additionally, note that, in some embodiments, parking lot 100 can correspond to any suitable group of curbside parking spaces, such as parking spaces along a particular block of a street.

As shown in FIG. 1A, each parking space can have a corresponding vehicle sensor. For example, as shown in FIG. 1A, parking space 104 has a vehicle sensor 102. In some embodiments, each vehicle sensor can be placed at any suitable location within the parking space. For example, as shown in FIG. 1A, each vehicle sensor can be placed at a center point within the parking space. As another example, in some embodiments, a vehicle sensor can be placed at any other suitable location, such as a front portion of the parking space, a back portion of the parking space, and/or at any other suitable location. Note that, in some embodiments, each vehicle sensor can be assigned an identifier that corresponds to the parking space in which it is placed.

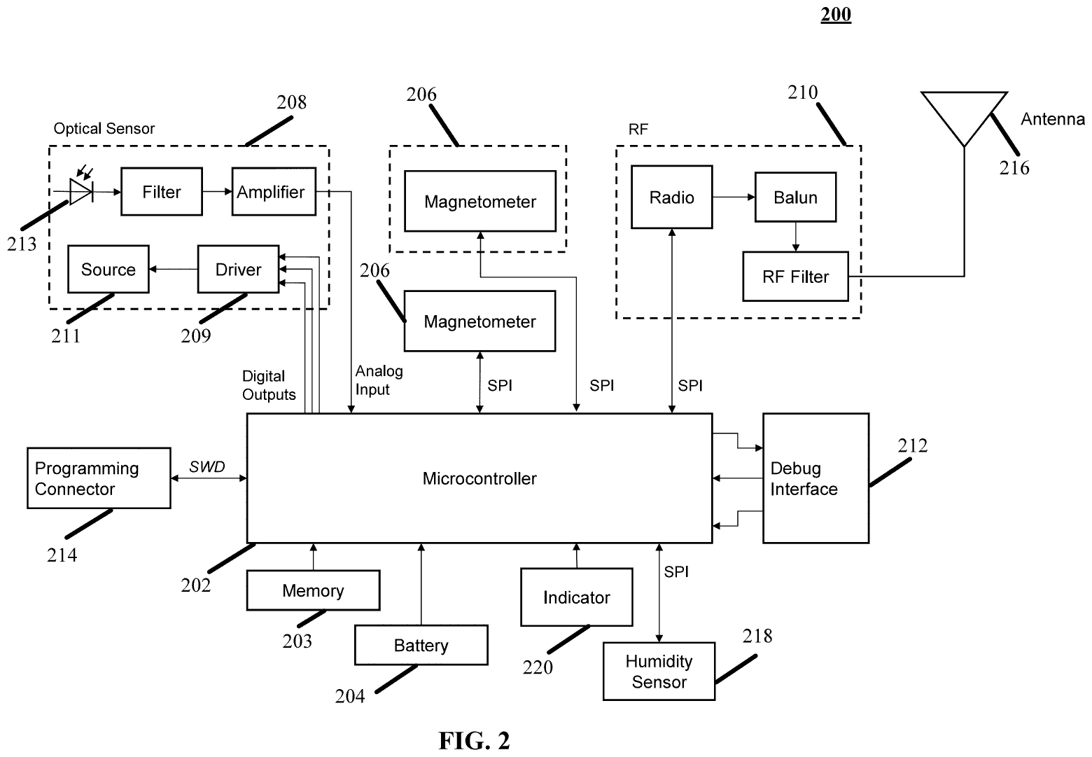

In some embodiments, vehicle sensor 102 can detect a vehicle (e.g., a car, a truck, a motorcycle, and/or any other suitable type of vehicle) over vehicle sensor 102 in any suitable manner. For example, in some embodiments, vehicle sensor 102 can detect a car using an optical sensor and/or a magnetometer, as discussed below in more detail in connection with FIGS. 2 and 3.

Turning to FIG. 1B, an example of a schematic diagram for transmitting parking information from vehicle sensors in accordance with some embodiments of the disclosed subject matter is shown.

As illustrated in FIG. 1B, each vehicle sensor, such as vehicle sensor 102, can transmit information to a gateway device 106. In some embodiments, vehicle sensor 102 can transmit information to gateway device 106 in any suitable manner, such as via any suitable radio transmission protocol operating at any suitable frequency (e.g., 915 MHz, 920 MHz, 925 MHz, and/or any other suitable frequency). In some embodiments, the transmitted information can include any suitable information, such as an identifier of vehicle sensor 102 (e.g., that uniquely identifies a location of vehicle sensor 102), magnetometer readings and/or optical sensor readings that can be used to determine whether a car is parked in a parking spot corresponding to vehicle sensor 102, and/or any other suitable information. In some embodiments, the transmitted information can be encrypted in any suitable manner and using any suitable encryption keys.

Note that, in some embodiments, vehicle sensor 102 can transmit information to gateway device 106 at any suitable time point(s). For example, in some embodiments, vehicle sensor 102 can be configured to transmit information to gateway device 106 in response to determining, based on readings from the magnetometer and/or the optical sensor, that a change in a parking status of the parking spot corresponding to vehicle sensor 102 has occurred (e.g., that a car has parked in the parking spot when at a previous time point no car was parked, that a car is no longer parked in a previously occupied parking spot, and/or any other suitable change in parking status). As another example, in some embodiments, vehicle sensor 102 can be configured to transmit information to gateway device 106 at any suitable predetermined frequency (e.g., once per minute, once per five minutes, once per ten minutes, and/or any other suitable frequency). As a more particular example, in some embodiments, vehicle sensor 102 can be configured to transmit information to gateway device 106 at a first predetermined frequency (e.g., once per five minutes, and/or any other suitable frequency) during a first time of day (e.g., between 7 am and 7 pm, on weekdays between 9 am and 5 pm, on weekends between 7 pm and midnight, and/or any other suitable time of day), and at a second predetermined frequency (e.g., once per hour, and/or any other suitable frequency) during a second time of day (e.g., between midnight and 8 am, on weekdays between 8 pm and 6 am, and/or any other suitable time of day).

In some embodiments, gateway device 106 can be any suitable device for receiving information from any suitable number of vehicle sensors (e.g., ten, twenty, one hundred, one thousand, and/or any other suitable number), and forwarding the received information to a server 108. For example, in some embodiments, gateway device 106 can receive data from a group of vehicle sensors located on the same level as gateway device 106 of a parking garage. As another example, in some embodiments, gateway device 106 can receive data from a group of vehicle sensors within a predetermined proximity to gateway device 106 (e.g., within 500 feet, within 2000 feet, and/or any other suitable predetermined proximity). Note that, in some embodiments, gateway device 106 can have any suitable power supply. For example, in some embodiments, gateway device 106 can be solar-powered, with solar panels located at any suitable position(s) on gateway device 106. As another example, in some embodiments, gateway device 106 can have any suitable type of battery (e.g., a replaceable battery, a rechargeable battery, and/or any other suitable type of battery).

In some embodiments, gateway device 106 can forward the information received from vehicle sensor 102 to server 108 in any suitable manner. For example, in some embodiments, gateway device 106 can forward the information via a cellular uplink. In some embodiments, gateway device 106 can transmit the information to server 108 using any suitable data transmission protocol, such as User Datagram Protocol (UDP), Hypertext Transfer Protocol (HTTP), HTTPS, MQ Telemetry Support (MQTT), and/or any other suitable protocol.

In some embodiments, server 108 can be any suitable server for collecting information from multiple vehicle sensors in different locations and providing any suitable parking information. For example, as shown in and discussed below in connection with FIG. 3, server 108 can present information indicating whether a particular parking space is occupied, a number of currently available parking spaces in a particular parking lot or garage, and/or any other suitable information. As another example, as shown in and discussed below in connection with FIGS. 5A, 5B, 5C, and 5D, server 108 can present an analysis of parking occupancy at particular locations, particular times of day, and/or any other suitable analysis.

Turning to FIG. 2, an example 200 of a schematic for hardware that can be used in a vehicle sensor in accordance with some embodiments of the disclosed subject matter is shown. As illustrated, vehicle sensor 200 can include a microcontroller 202 (or any other suitable hardware processor such as a microprocessor, a digital signal processor, dedicated logic a programmable gate array, an application specific integrated circuit (ASIC), etc.), a memory 203, a battery 204, one or more magnetometer(s) 206, an optical sensor 208, a radio frequency (RF) interface 210, a debug interface 212, a programming connector 214, an antenna 216, a humidity sensor 218 and/or a feedback indicator 220.

In some embodiments, microcontroller 202 can execute any suitable instructions or computer programs associated with the vehicle sensor. For example, in some embodiments, microcontroller 202 can execute any suitable instructions for collecting and/or or storing readings from magnetometer(s) 206, collecting and/or storing readings from optical sensor 208, transmitting readings to a gateway device via RF interface 210, updating firmware on microcontroller 202 (e.g., using programming connector 214, and/or in any other suitable manner), and/or perform any other suitable function(s). As another example, in some embodiments, microcontroller 202 can encrypt messages transmitted to a gateway device using any suitable encryption protocol(s). In some embodiments, any suitable encryption keys can be stored in memory 203 or in a memory of microcontroller 202. In some embodiments, microcontroller 202 can execute instructions using any suitable computer language, such as C, C++, Java, Python, Go, and/or any other suitable computer language.

In some embodiments, memory 203 can be any suitable memory and/or storage for storing programs, data, and/or any other suitable information in some embodiments. For example, memory 203 can include random access memory, read-only memory, flash memory, hard disk storage, optical media, and/or any other suitable memory.

In some embodiments, battery 204 can be any suitable type of battery that serves as a power source for the vehicle sensor. For example, in some embodiments, battery 204 can be a non-replaceable battery. As another example, in some embodiments, battery 204 can be a replaceable battery. Note that, in some embodiments, battery 204 can have any suitable characteristics such that the battery can provide any suitable voltage (e.g., between 2.5 V and 3.6 V, and/or any other suitable voltage) over its intended lifetime. Additionally, note that, in some embodiments, battery 204 can have any suitable characteristics such that battery 204 can have any suitable intended battery life (e.g., five years, ten years, fifteen years, and/or any other suitable intended battery life). Also note that, in some embodiments, battery 204 can be a rechargeable battery, where the battery may be charged using solar power or by harvesting other available power sources in-situ. For example, the vehicle sensor can include solar panels located at any suitable position(s) on the vehicle sensor in which power can be converted and/or otherwise transmitted from one or more solar panels to battery 204 via one or more electrical connectors (e.g., wires, cables, and/or any other suitable type of electrical connectors).

In some embodiments, remaining charge and/or battery life of battery 204 can be indicated in any suitable manner. In some embodiments, microcontroller 202 can indicate battery life of battery 204. For example, in some embodiments, microcontroller 202 can sample the voltage on battery 204 using an internal or external analog to digital converter. In another example, in some embodiments, microcontroller 202 can first sample the voltage on battery 204 and then compare the voltage to a threshold. Alternatively, in some embodiments, the battery voltage can be compared to a threshold using a comparator. Based on the comparison of the battery voltage to the threshold (whether performed digitally or based on analog signals), the microcontroller can determine whether the battery life is OK or low. In some embodiments, vehicle sensor 200 can transmit a signal to gateway 106 indicating battery life of battery 204. Note that as discussed in connection with FIG. 1B, vehicle sensor 200 can transmit information, including measurements indicating battery life, at any suitable time point(s). For example, in some embodiments, vehicle sensor 200 can transmit a measurement of the battery voltage to gateway 106 where the measurement can be further processed (either by the gateway 106, server 108, and/or any other suitable entity) to indicate battery life. In another example, in some embodiments, vehicle sensor 200 can transmit a signal (e.g., “low battery”) indicating a voltage from the battery measured by microcontroller 202 is less than a threshold voltage. Alternatively, vehicle sensor 200 can transmit a signal (e.g., “battery life OK”) indicating the battery life is greater than a threshold.

In some embodiments, magnetometer(s) 206 can be any suitable sensor that senses a change in a magnetic field. For example, in some embodiments, magnetometer(s) 206 can be a magnetometer that detects a change in a magnetic field in response to an object being placed over and/or in proximity to magnetometer(s) 206, such as a car or other vehicle. Note that, in some embodiments, magnetometer(s) 206 can be any suitable type of magnetometer that measure a magnetic field along any suitable vector (e.g., any suitable (X, Y, Z) vector). In some embodiments, magnetometer(s) 206 can transmit readings to microcontroller 202 via a serial interface, as shown in FIG. 2. For example, such an interface can include a Serial Peripheral Interface (SPI) interface, a Universal Asynchronous Receiver/Transmitter (UART) interface, an Inter-Integrated Circuit (I2C) interface, and/or any other suitable interface.

In a more particular example, one or more of magnetometer(s) 206 can be a low-power magnetometer that is positioned to detect whether a curb space or a parking space is being occupied by a vehicle.

In some embodiments, optical sensor 208 can include any suitable components. For example, in some embodiments, optical sensor 208 can include a light source 211 and a light sensor 213. In some embodiments, the amount of reflected light measured by light sensor 213 can indicate whether or not an object (e.g., a car) is positioned over the vehicle sensor. In some embodiments, optical sensor 208 can measure time-of-flight of photos transmitted and detected by the optical sensor to determine the distance between the sensor and one or more objects (e.g., debris) positioned over the vehicle sensor. In some embodiments, to measure time-of-flight, optical sensor 208 can be any suitable time-of-flight sensor, such as part VL53L3CXV0DH/1 available from STMicroelectronics of Geneva, Switzerland.

In some embodiments, light source 211 can be an LED, laser and/or any other suitable light source. In some embodiments, light source can emit light in any suitable wavelength (e.g., infrared light, visible light, and/or any other suitable wavelength). Note that, in some embodiments, the emitted light can be of any suitable waveform, e.g., pulses of light, a constant emission at a particular wavelength, and/or any other suitable type of emitted light. In some embodiments, light sensor 213 can be a photodiode, avalanche detector, photo-multiplier tube, photon counting detector, and/or any other suitable detector. In some embodiments, light sensor can be sensitive to wavelengths of light emitted by light source 211 and/or any other suitable wavelength.

In some embodiments, optical sensor 208 can include any other suitable components, such as a driver 209, filter, an amplifier, and/or any other suitable components. As shown in FIG. 2, a connection between optical sensor 208 and microcontroller 202 can include any suitable materials and/or components. For example, as shown in FIG. 2, light source 211 can be connected to microcontroller 202 via one or more digital output channels. As another example, in some embodiments, an amplifier of optical sensor 208 that amplifies a measurement of light sensor 213 can be connected to microcontroller 202 via any suitable analog General Purpose I/O (GPIO) interface.

In some embodiments, the vehicle sensor can make pulsed Doppler radar measurements in order to determine the distance between the vehicle sensor and an object above the sensor. For example, the vehicle sensor can include a pulsed coherent radar sensor, such as part A111-001-T&R available from Acconeer AB.

Note that, in some embodiments, a measurement using optical sensor 208 can be triggered based on a reading from one or more of magnetometer(s) 206. For example, in some embodiments, in response to detecting a change in a magnetic field based on a reading from one or more of magnetometer(s) 206, microcontroller 202 can trigger or otherwise activate optical sensor 208. Note that, in some embodiments, when optical sensor 208 is a time-of-flight sensor, microcontroller 202 can trigger or otherwise activate a time-of-flight measurement. In a more particular example, one or more of magnetometer(s) 206 can be a low-power magnetometer that is positioned to detect whether a curb space or a parking space is being occupied by a vehicle, where, in response to detecting that a curb space or a parking space may be occupied by a vehicle based on a particular change in magnetic field, one or more of magnetometer(s) 206 and/or microcontroller 202 can transmit an instruction to turn on, wake up, or otherwise activate optical sensor 208, which can then verify usage of the curb space or parking space by the vehicle.

In some embodiments, a second of the one or more magnetometer(s) 206 can be used instead of or in addition to optical sensor 208 confirm occupancy. For example, the second of the one or more magnetometer(s) 206 can be oriented at any angle relative to a first of the one or more magnetometer(s) 206 and can sample any suitable vector (e.g., any suitable (X, Y, Z) vector). As a particular example, the second of the one or more magnetometer(s) 206 can measure a magnetic field along a vector which is +45° relative to the first of the one or more magnetometer(s) 206, or any other suitable angle. In another example, the second of the one or more magnetometer(s) 206 can take a more sensitive measurement than the first of the one or more magnetometer(s) 206, which can be figured to take low-power magnetometer measurements.

This can, for example, allow the wireless occupancy sensor to have a low power draw in which a low-power magnetometer is used to detect changes in magnetic field and activating a higher power consuming sensor (e.g., optical sensor 208 or a second magnetometer 206) upon the change in the magnetic field being greater than a particular threshold value or meeting predetermined criteria.

In some embodiments, RF interface 210 can be used to transmit information from the vehicle sensor to a gateway device using any suitable radio transmission protocol and using any suitable frequency. For example, in some embodiments, RF interface 210 can include any suitable encoder, transmitter, transceiver, and/or any other suitable components. In some embodiments, RF interface 210 can communicate with microcontroller 202 via an SPI interface, as shown.

In some embodiments, debug interface 212 can be used to debug any suitable functionality of the vehicle sensor.

In some embodiments, antenna 216 can be any suitable antenna for use with RF interface 210.

In some embodiments, humidity sensor 218 can be any suitable humidity sensor. In some embodiments, humidity sensor 218 can be an integrated circuit which can include any suitable sensors. For example, in some embodiments, humidity sensor 218 can integrate a humidity sensor, temperature sensor, pressure sensor, and/or any other suitable sensors into a single sensor package. In some embodiments, humidity sensor 218 can be part number BME 280 available from Bosch Sensortec GmbH of Reutlingen, Germany. In some embodiments, humidity sensor 218 can transmit humidity, temperature, pressure, and/or any other suitable readings to microcontroller 202 via a serial interface, as shown in FIG. 2 and described above in connection with magnetometer(s) 206. In some embodiments, humidity sensor 218 can transmit readings to microcontroller 202 at any suitable time, with any suitable rate or any suitable frequency. For example, humidity sensor 218 can send sensor data once per hour, once per day, and/or at any other suitable frequency and/or asynchronously based on any suitable criteria or criterion. In another example, humidity sensor 218 can send sensor data in response to any suitable request from microcontroller 202.

In some embodiments, feedback indicator 220 can indicate the status of vehicle sensor 200 through any suitable mechanism. In some embodiments, feedback indicator 220 can include can a light emitting diode (LED) and/or any suitable light source of any suitable color light. In some embodiments, an LED of feedback indicator 220 can be visible on a top portion or through a window of vehicle sensor 200. In some embodiments, an LED of feedback indicator 220 can indicate a status of vehicle sensor 200 in any suitable manner. For example, in some embodiments, an LED of feedback indicator 220 can indicate status by being on, off, and/or blinking at any suitable frequency for any suitable duty cycle. Additionally or alternatively, any suitable one or more blinking patterns can indicate one or more of a pairing mode, a wake-up state, restarting, an update mode, an error state, and/or any other suitable device status. Similarly, an always-on or always-off mode of an LED on feedback indicator 220 can indicate a normally functioning vehicle sensor 200 and/or any other suitable device status.

In some embodiments, feedback indicator 220 can include a display that is visible on the top of the vehicle sensor (e.g., through a window of the vehicle sensor). The display can present any suitable status information (e.g., as described above).

In some embodiments, feedback indicator 220 can include a sound source (such as a piezo speaker) that produces sounds to indicate status. For example, in some embodiments, the sounds source could generate tones in the same way that an LED could present light to indicate status as described above.

In some embodiments, the vehicle sensor can be installed at a parking space and/or any other suitable location using any suitable approach. For example, a vehicle sensor can be installed at a central point of a parking spot by applying an epoxy adhesive to a rear portion of the vehicle sensor. In another example, a vehicle sensor can be temporarily installed at a particular portion of a parking spot by positioning a butyl pad between a rear portion of the vehicle sensor and a particular point within a parking spot. In yet another example, a vehicle sensor can be installed on the curb portion of a street that permits parking by applying an adhesive to a rear portion of the vehicle sensor and positioning the vehicle sensor on a desired portion of the curb.

Turning to FIG. 3, an illustrative example 300 of a process for generating and presenting parking information using one or more vehicle sensors in accordance with some embodiments of the disclosed subject matter is shown. In some embodiments, blocks of process 300 can be executed by any suitable device, such as a server that receives parking information transmitted from a gateway device, as shown in and described above in connection with FIG. 1B.

Process 300 can begin at 302 by receiving, at a server from a gateway device, data from a vehicle sensor communicatively coupled to the gateway device. As shown in and described above in connection with FIGS. 1A and 1B, the vehicle sensor can be any suitable wireless occupancy sensor that detects a presence of a vehicle above the sensor. For example, as described above in connection with FIGS. 1A and 1B, the vehicle sensor can collect any suitable readings from a magnetometer and/or an optical sensor that can be used to determine a presence of a vehicle. In some embodiments, the data received by the server can be any suitable data, such as one or more magnetometer readings, one or more readings from an optical sensor, one or more data points from an amplifier connected to a magnetometer and/or optical sensor, and/or any other suitable data. For example, in some embodiments, the data can include one or more magnetic field vectors using (X, Y, Z) axes. As another example, in some embodiments, the data can include optical reflectivity data measured by an optical sensor, as shown in and described above in connection with FIGS. 1A, 1B, and 2.

Note that, in some embodiments, data received from a particular vehicle sensor can be associated with an identifier of a particular parking spot the vehicle sensor is located at. In some embodiments, the identifier can additionally indicate a particular parking lot or parking garage the vehicle sensor is located at. For example, in some embodiments, the identifier can include a parking lot identifier (e.g., “SW Corner of Street 1/Avenue 1,” and/or any other lot or garage identifier) and a parking spot identifier (e.g., “#314,” “#512,” and/or any other suitable parking spot identifier). In instances in which the parking spot is a curbside spot along a street, the identifier can indicate the block the parking spot is located on by identifying one or more streets that define the block as well as a side of the street (e.g., the north side, the south side, the east side, the west side, and/or any other suitable side) the parking spot is located on.

Note that, in some embodiments, process 300 can perform any suitable verification in response to receiving a message from a gateway device. For example, in some embodiments, process 300 can verify or validate that the message was not corrupted in transit in any suitable manner. Additionally, note that, in some embodiments, process 300 can log the message in any suitable manner. For example, in some embodiments, process 300 can store the received message in any suitable database. As another example, in some embodiments, process 300 can store received sensor readings in any suitable cache. Note that, in some embodiments, stored messages and/or data can be accessed at any suitable time for debugging.

Additionally, note that, in instances in which the data received from the gateway device is encrypted in any manner (e.g., encrypted by the vehicle sensor as described above in connection with FIG. 2, encrypted by the gateway device, and/or encrypted by any other suitable device), process 300 can decrypt the data in any suitable manner. For example, in some embodiments, process 300 can use any suitable public key or private key to decrypt a received message.

In some embodiments, the data can be received by the server in any suitable manner. For example, in some embodiments, the data can be received by an event receiver executing on the server that receives a message that includes the data. Continuing with this example, in some embodiments, the event receiver can, in response to receiving a message from a gateway device, cause additional blocks of process 300 to be executed, as described below.

At 304, process 300 can determine whether a vehicle (e.g., a car, a truck, a motorcycle, etc.) is positioned over the vehicle sensor based on the data. In some embodiments, process 300 can determine whether a vehicle is parked over the vehicle sensor using any suitable technique(s). For example, in some embodiments, process 300 can determine whether a vehicle is positioned over the vehicle sensor using optical reflectivity data that indicates an amount of reflected light. As a more particular example, in some embodiments, process 300 can determine that a vehicle is positioned over the vehicle sensor in response to determining that more light is reflected than a baseline amount of reflected light at a time when no vehicle is positioned over the vehicle sensor. As a specific example, in some embodiments, process 300 can determine that a vehicle is positioned over the vehicle sensor in response to determining that the amount of reflected light exceeds a predetermined threshold.

Note that, in some embodiments, the gateway device can determine whether a vehicle is positioned over the vehicle sensor. In some such embodiments, rather than receiving data from the vehicle sensor that is forwarded by the gateway device to the server, the server can receive information indicating the determination by the gateway device of whether a vehicle is positioned over the vehicle sensor.

At 306, process 300 can update a parking database based on the determination. For example, in some embodiments, process 300 can use an identifier included in the data received at 302 as a database key to identify the parking spot in the parking database. Continuing with this example, process 300 can then update the database using the determination from 304. As a more particular example, in response to determining that a vehicle is present in the parking spot, process 300 can update the database to indicate that the parking spot is currently occupied. As another more particular example, in an instance in which the determination at 304 is that there is no vehicle present, and in which the database previously indicated that the parking spot had been occupied, process 300 can update the database to indicate that the parking spot is currently unoccupied. Note that, in some embodiments, process 300 can update the database in connection with a timestamp that indicates a time at which the data was collected by the vehicle sensor. In some embodiments, the timestamp can be used for any suitable function(s), such as to determine whether a vehicle has been parked in the parking spot for longer than is allowed, to determine an average duration of time vehicles park in particular parking lots, and/or for any other suitable information.

Note that, in some embodiments, the parking database can store any suitable information about parking lots and/or individual parking spots. For example, in some embodiments, the parking database can store information about an individual parking spot, such as a time limit available for that parking spot, whether the parking spot is reserved for a particular group of people or a particular activity (e.g., whether the parking spot is a handicapped spot, a parking spot reserved for a quick pick-up in a store, a parking spot reserved for deliveries, and/or any other suitable type of reserved spot), whether the parking spot has a station for charging electric vehicles, and/or any other suitable information. As another example, in some embodiments, the parking database can store information about the parking lot or garage the parking spot is located in, such as a total number of parking spots in the lot or garage, a total number of a particular type of parking spot (e.g., handicapped-reserved spots, electrical vehicle charging spots, and/or any other suitable type of parking spot).

Additionally, note that, in instances in which a particular parking spot is associated with any particular criteria for parking, for example, that a particular fee must be paid, that parking is restricted to a predetermined number of hours (e.g., two hours, five hours, and/or any other suitable number of hours), process 300 can determine, via the parking database, whether a vehicle currently occupying a parking spot is in compliance with the criteria. For example, in an instance in which a parking spot may only be occupied for two hours, process 300 can determine whether a vehicle currently occupying the parking spot has been parked for more than two hours. In some embodiments, process 300 can transmit a notification to any suitable entity in response to determining that a vehicle does not meet criteria associated with the parking spot, such as to a parking enforcement agency, an administrator of the parking lot or garage the parking spot is located in, and/or to any other suitable entity.

At 308, process 300 can receive, from a user device, a request to present parking information. In some embodiments, the request can be from a user device associated with any suitable user. For example, in some embodiments, the request can be from a user who wants to find a parking space. As a more particular example, in some embodiments, the request can be from a user who wants to view user interfaces that show a number of available parking spaces in a particular parking lot or garage, a number of available parking spaces of a particular type (e.g., handicapped-reserved spots, reserved for deliveries, equipped with electrical vehicle charging ports, and/or any other suitable type of parking spot) available in a particular parking lot or garage, and/or any other suitable parking information. As another example, in some embodiments, the request can be from a user who wants to view or analyze parking metrics in a geographical region, such as an administrator of a parking agency, an administrator at an urban planning agency, and/or any other suitable type of user. In some embodiments, the request from the user device can be via a particular application executing on the user device (e.g., an application for finding a parking space, and/or any other suitable type of application). In some embodiments, the request from the user device can be via a website presented in a browser of the user device (e.g., a website for presenting parking metrics or analysis, a website for finding a parking space, and/or any other suitable type of website).

At 310, process 300 can cause a user interface to be presented on the user device that presents the requested parking information. Note that, in some embodiments, information presented in the user interface can be retrieved from the parking database described above in connection with 306.

Turning to FIG. 4A, an illustrative example 400 of a user interface for presenting parking space information in accordance with some embodiments of the disclosed subject matter is shown.

In some embodiments, user interface 400 can include a map 401 that indicates different parking lots or garages in a geographical region (e.g., in a city, in a town, in a neighborhood, and/or any other suitable geographical region), such as a garage 402. Note that, in some embodiments, map 401 can be zoomed in or out and/or manipulated in any suitable manner, such as via a touchscreen of the device the map is presented on, via a mouse, and/or in any other suitable manner.

In some embodiments, user interface 400 can include a hierarchical list 403 that presents information relating to different parking lots or garages. For example, as shown in user interface 400, a top level of hierarchical list 403 can list a name of a geographical region shown in map 401 (e.g., “Plymouth”). Continuing with this example, as shown in user interface 400, the top level of hierarchical list 403 can be expanded to show different parking lots or garages located in the geographical region (e.g., “1500 Plymouth,” “1502 Plymouth,” “1625 Plymouth”). Continuing further with this example, in some embodiments, any of the parking lots or garages can be expanded within hierarchical list 403 to show different regions or portions of the selected parking lot or garage (e.g., Roof 404 as shown in FIG. 4A, the ground floor, the first floor, etc.). Continuing still further with this example, in some embodiments, a particular region or portion of the parking lot or garage can be expanded to show information about individual parking spaces within the region of the parking lot, such as parking spot 406. In some embodiments, the information can indicate any suitable information, such as whether the parking spot is available or occupied, whether a vehicle currently parked in the spot has overstayed a time limit associated with the spot, and/or any other suitable information.

In some embodiments, the parking information associated with individual parking spots can be presented in a map format, as shown in FIG. 4B. Turning to FIG. 4B, an example 450 of a user interface for presenting parking information in a map format in accordance with some embodiments of the disclosed subject matter is shown.

As illustrated, user interface 450 can present a map of different parking spaces within a parking lot or garage, such as parking spot 452. Note that, in some embodiments, each parking spot can be colored or shaded in a visual manner that indicates a current status of the parking spot (e.g., available, occupied, the current occupant has overstayed a time limit, and/or any other suitable status). Additionally, as shown in user interface 450, parking spot 452 can include an icon 454 that indicates a parking spot type associated with the parking spot. For example, in some embodiments, icon 454 can indicate that the parking spot has equipment for charging an electric vehicle, that the parking spot is a handicapped-reserved spot, that the parking spot is reserved for quick deliveries, and/or any other suitable parking spot type.

Turning to FIGS. 5A, 5B, 5C, and 5D, examples of user interfaces for presenting an analysis of parking information in accordance with some embodiments of the disclosed subject matter is shown. In some embodiments, the user interfaces shown in FIGS. 5A, 5B, 5C, and/or 5D can be presented on a user device of a user or an entity who has access to the parking database for planning (e.g., planning availability of parking resources, urban planning, etc.) and/or parking enforcement.

FIG. 5A shows an illustrative example 500 of a user interface for showing availability of different types (e.g., standard parking spots, electric vehicle parking spots, carpool parking spots, expectant mother parking spots, motorcycle parking spots, handicapped parking spots, and/or any other suitable type of parking spot) of parking spaces within a particular parking lot or garage in accordance with some embodiments of the disclosed subject matter. As illustrated, user interface 500 can show a percentage of currently available spots of each type. Additionally, as shown, user interface 500 can indicate absolute numbers of each type of parking spot and an absolute number of each type of parking spot that is currently available. In some embodiments, user interface 500 can indicate a threshold line 502 (e.g., 15%, 20%, and/or any other suitable threshold) that indicates types of parking spots for which a current availability is below the threshold.

Turning to FIG. 5B, an illustrative example 510 of a user interface for presenting parking spot availability within a particular parking lot or garage at different times of day is shown in accordance with some embodiments of the disclosed subject matter. As illustrated, in some embodiments, user interface 510 can include a threshold line 512 that indicates a threshold level of availability (e.g., 15%, 20%, and/or any other suitable threshold). As shown in FIG. 5B, threshold line 512 can allow a viewer of user interface 510 to easily identify times of day when parking availability is below the threshold corresponding to threshold line 512.

Turning to FIG. 5C, an illustrative example 520 of a user interface for presenting an analysis of parking data is shown in accordance with some embodiments of the disclosed subject matter. As illustrated, user interface 520 can present any suitable information, such as a current availability in a particular parking lot or garage (e.g., an absolute number of available parking spots, a percentage of parking spots that are currently available, and/or any other suitable availability metric), a number of vehicles that are currently occupying parking spots beyond a time limit, an average time duration of the day during which more than a predetermined percentage of the parking lot or garage is occupied, a graph of parking availability at different times of day, and/or any other suitable information. Note that, in some embodiments, the information can be presented for a particular parking lot and/or garage. Additionally or alternatively, in some embodiments, the information can be collected and presented for multiple parking lots and/or garages in a particular geographical region.

Turning to FIG. 5D, an illustrative example 530 of a user interface for presenting an analysis of parking information by parking spot type is shown in accordance with some embodiments of the disclosed subject matter. As illustrated in user interface 530, an average percentage occupancy of different types of parking spots can be shown over any suitable time period (e.g., from 8 am-6 pm on weekdays, at all times on weekdays, on weekends, and/or any other suitable time period).

Note that the information provided in the user interfaces shown in FIGS. 5A, 5B, 5C, and 5D can be used for any suitable purpose. For example, a user viewing the information shown in FIGS. 5A, 5B, 5C, and/or 5D that indicates relatively low availability of particular types of parking spots at particular times can determine that additional parking of that type should be added at the particular times. As a more particular example, in an instance in which the information indicates that less than a predetermined threshold of parking spots of a particular type (e.g., for charging electric vehicles, and/or any other suitable type of parking spot) are available at a particular time of day on average, a user (e.g. associated with administration of a particular parking lot or garage) can determine that additional parking spots are to be added of that type and/or that parking spot types should be reallocated. Moreover, referring back to FIG. 3, in some embodiments, process 300 can automatically transmit a notification or alert to a particular user device in response to determining that parking spots of a particular type have less than a predetermined threshold of availability at particular times of day and/or on particular days of the week.

Note that, in some embodiments, process 300 can retrieve the data used to generate the information presented in the user interfaces of FIGS. 4A, 4B, 5A, 5B, 5C, and/or 5D in any suitable manner. For example, in some embodiments, process 300 can transmit a query to the parking database requesting parking data with any suitable parameters. As a more particular example, the query can specify a particular parking lot or garage. As another more particular example, the query can specify timing information corresponding to data that is to be retrieved (e.g., data corresponding to a particular time of day or particular days of the week, data from the past week, and/or any other suitable timing information). As another more particular example, the query can indicate that data corresponding to particular types of parking spots is to be retrieved (e.g., handicapped-reserved spots, electrical vehicle charging spots, spots reserved for quick deliveries or drop-offs, and/or any other suitable types of parking spots). Note that, in some such embodiments, a query to the parking database can include any suitable combination of query criteria, such as a combination of timing information and parking spot type information.

In some embodiments, process 300 can then loop back to 302 and can receive additional vehicle sensor data.

In some embodiments, the mechanisms described herein can perform any other suitable action(s) or function(s) using data from a vehicle sensor as shown in and described above in connection with FIGS. 1A, 1B, and 2. For example, in some embodiments, data from vehicle sensors can be used to dynamically set prices for parking based on current availability. As a more particular example, in some embodiments, the parking database described above in connection with FIG. 3 can be queried to determine a current parking availability in a particular parking lot or garage. Continuing further with this particular example, in some embodiments, a price can be determined for a parking spot based on the current availability, such that the price is relatively lower in instances in which the current availability is relatively higher (e.g., above a predetermined availability threshold) and relatively higher in instances in which the current availability is relatively lower (e.g., below a predetermined availability threshold). Note that, in some embodiments, prices can be determined for different types of parking spots. For example, in some embodiments, a first price can be determined for a first type of parking spot (e.g., an electric vehicle charging spot) based on current availability of the first type of parking spot, and a second price can be determined for a second type of parking spot (e.g., general parking) based on current availability of the second type of parking spot.

As another example, in some embodiments, a vehicle sensor as shown in and described above in connection with FIGS. 1A, 1B, and 2 can be used at traffic intersections for any suitable purpose. For example, in some embodiments, a vehicle sensor can be used to toggle a traffic light. As a more particular example, in some embodiments, a traffic light on a busy road can be turned to red in response to detecting a vehicle over a vehicle sensor placed on a less busy road at an intersection point with the busy road.

As yet another example, in some embodiments, a vehicle sensor as shown in and described above in connection with FIGS. 1A, 1B, and 2 can be used to dynamically route vehicles to curbside parking or drop off spots. For example, in an instance in which a vehicle is to stop along a street to make a delivery (e.g., a package delivery, a food delivery, and/or any other suitable type of delivery) and/or to pick up or drop off passengers in a ride-sharing vehicle, the vehicle can receive dynamic directions to a currently available parking spot based on current occupancy as detected by one or more vehicle sensors in the vicinity of the drop off location. As a more particular example, in an instance in which a vehicle is to stop on a particular block in which a drop-off address is located to make a delivery, a user device associated with the vehicle (e.g., associated with a driver of the vehicle, a vehicle information and entertainment device, and/or any other suitable type of user device) can receive an indication of an available curbside spot closest to the drop-off location such that the vehicle can drive to the available curbside spot. In some such embodiments, the user device can be configured to automatically query the parking database (e.g., via an application executing on the user device, and/or in any other suitable manner) in response to detecting that the user device has arrived within a predetermined proximity of the drop-off location (e.g., within 0.25 miles, within 0.3 miles, and/or any other suitable proximity) Continuing further with this example, in some embodiments, the parking database can then return an identifier (e.g., a GPS location, and/or any other suitable identifying information) corresponding to a vehicle sensor corresponding to a currently unoccupied curbside drop-off point nearest to the drop-off location. Continuing still further with this example, in some embodiments, navigation software executing on the user device can be configured to direct the vehicle or a driver of the vehicle to the specified available location. Note that, in some such embodiments, the navigation techniques as described above can be implemented by a human or by an autonomous vehicle.

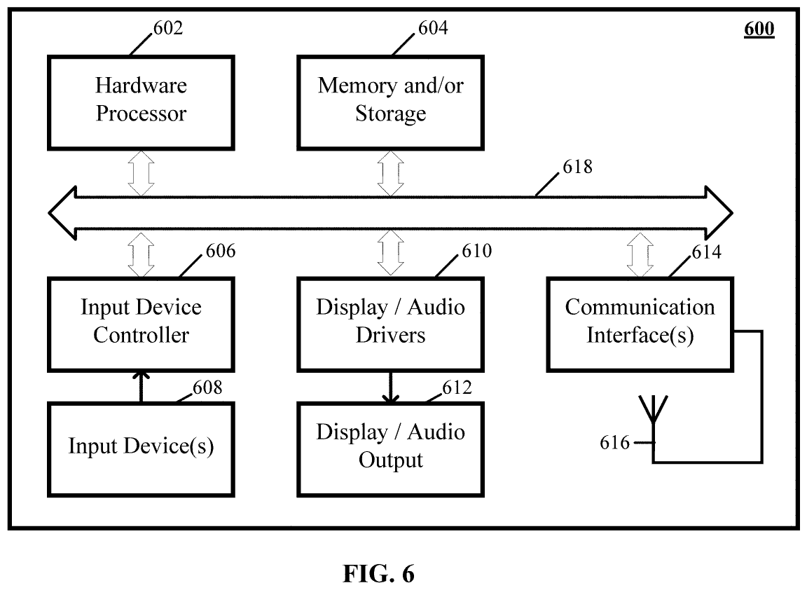

A server, a gateway device, and/or a user device can be implemented using any suitable hardware in some embodiments. For example, in some embodiments, a device can be implemented using any suitable general-purpose computer or special-purpose computer. For example, a mobile phone may be implemented using a special-purpose computer. Any such general-purpose computer or special-purpose computer can include any suitable hardware. For example, as illustrated in example hardware 600 of FIG. 6, such hardware can include hardware processor 602, memory and/or storage 604, an input device controller 606, an input device 608, display/audio drivers 610, display and audio output circuitry 612, communication interface(s) 614, an antenna 616, and a bus 618.

Hardware processor 602 can include any suitable hardware processor, such as a microprocessor, a micro-controller, digital signal processor(s), dedicated logic, and/or any other suitable circuitry for controlling the functioning of a general-purpose computer or a special-purpose computer in some embodiments. In some embodiments, hardware processor 602 can be controlled by a server program stored in memory and/or storage of a server. In some embodiments, hardware processor 602 can be controlled by a computer program stored in memory and/or storage 604 of a gateway device and/or a user device.

Memory and/or storage 604 can be any suitable memory and/or storage for storing programs, data, and/or any other suitable information in some embodiments. For example, memory and/or storage 604 can include random access memory, read-only memory, flash memory, hard disk storage, optical media, and/or any other suitable memory.

Input device controller 606 can be any suitable circuitry for controlling and receiving input from one or more input devices 608 in some embodiments. For example, input device controller 606 can be circuitry for receiving input from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 610 can be any suitable circuitry for controlling and driving output to one or more display/audio output devices 612 in some embodiments. For example, display/audio drivers 610 can be circuitry for driving a touchscreen, a flat-panel display, a cathode ray tube display, a projector, a speaker or speakers, and/or any other suitable display and/or presentation devices.

Communication interface(s) 614 can be any suitable circuitry for interfacing with one or more communication networks. For example, interface(s) 614 can include network interface card circuitry, wireless communication circuitry, and/or any other suitable type of communication network circuitry.

Antenna 616 can be any suitable one or more antennas for wirelessly communicating with a communication network in some embodiments. In some embodiments, antenna 616 can be omitted.

Bus 618 can be any suitable mechanism for communicating between two or more components 602, 604, 606, 610, and 614 in some embodiments.

Any other suitable components can be included in hardware 600 in accordance with some embodiments.

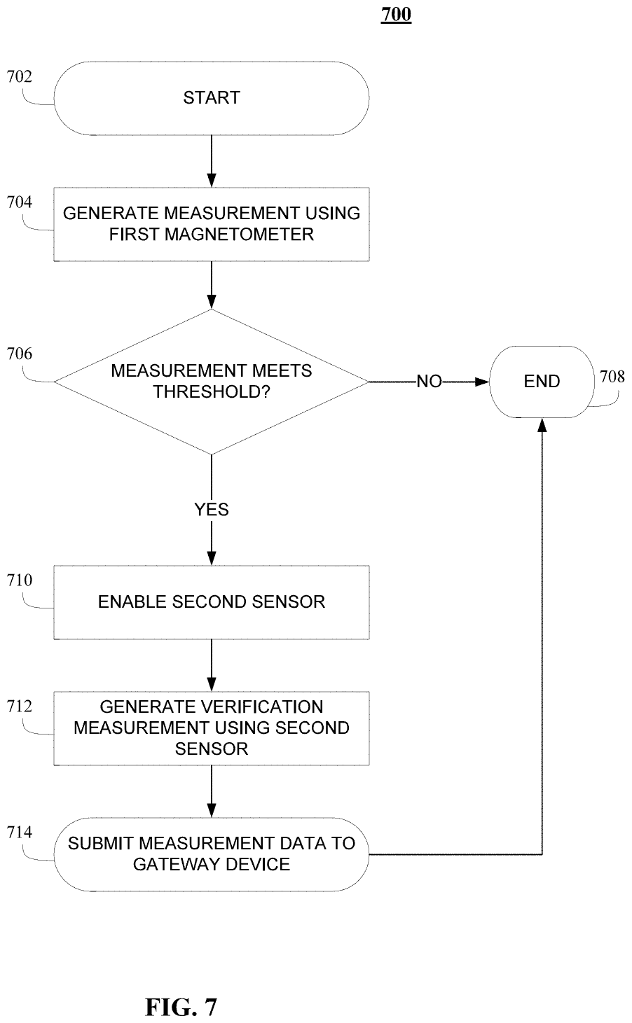

Turning to FIG. 7, an example 700 of a process for occupancy sensing (e.g., to sense the presence of a vehicle) in accordance with some embodiments is shown. This process may be executed by microcontroller 202 of FIG. 2 based on any suitable instructions in some embodiments.

As illustrated, process 700 can begin at 702. This process can begin on any suitable basis. For example, in some embodiments, process 700 can begin periodically based any suitable criteria. More particularly, for example, the process can begin every given time period and can vary the given time period based on the time of day, based on the day of week, based on the time of year, and/or based on any other suitable criteria or criterion. As another example, in some embodiments, process 700 can begin by receiving an interrupt signal from a first magnetometer indicating that it has sensed the presence of something. This signal can be received from any suitable magnetometer in any suitable manner in some embodiments. For example, in some embodiments, the signal can be received from magnetometer 206 of FIG. 2.

Next, at 704, process 700 can generate a measurement using the first magnetometer. This measurement can be generated in any suitable manner in some embodiments. For example, in some embodiments, this measurement can be generated by microcontroller 202 causing the magnetometer to take a measurement and provide data of the measurement to the microcontroller.

Then, at 706, process 700 can determine whether the measurement meets a threshold. Any suitable threshold, such as 200 millimeneters can be used in some embodiments. Meeting a threshold can be the measurement being greater than the threshold or greater than or equal to the threshold in some embodiments.

If the measurement is determined at 706 as not meeting the threshold, then process can end at 708.

Otherwise, process 700 can branch to 710 at which it can enable a second sensor. Any suitable second sensor can be enabled and the second sensor can be enabled in any suitable manner. For example, the second sensor can be a second magnetometer, an optical sensor, a pressure sensor, and/or any other suitable sensor for detecting occupancy. More particularly, in the case of the second sensor being a magnetometer, the second sensor can be a magnetometer 206 of FIG. 2. In the case of second sensor being an optical sensor, the second sensor can be optical sensor 208 of FIG. 2.

Next, at 712, process 700 can generate a verification measurement using the second sensor. This verification measurement can be generated in any suitable manner in some embodiments. For example, in some embodiments, this measurement can be generated by microcontroller 202 causing a second magnetometer to take a measurement and provide data of the measurement to the microcontroller. As another example, in some embodiments, this measurement can be generated by microcontroller 202 causing the magnetometer to take a measurement and provide data of the measurement to the microcontroller.

Then, at 714, process 700 can submit measurement data to a gateway device. Any suitable measurement data can be submitted, and the measurement data can be submitted in any suitable manner. For example, the measurement data can include data relating to the measurements generated at 704 and/or 712. As another example, the measurement data can be submitted by wirelessly transmitting the data to the gateway device. The data can be submitted to any suitable gateway device in some embodiments. For example, the gateway device can be gateway device 106 of FIG. 1B.

Finally, after submitting the measurement data to the gateway device at 714, process can end at 708.

Turning to FIG. 8A, an exploded-view illustration of example internal components 800 of a vehicle sensor in accordance with some embodiments is shown. As illustrated, in some embodiments, internal components 800 can include a sub-assembly 802, a battery 804, a mounting bracket 806, a printed circuit board 808, mounting hardware 810, and an antenna 812.

As shown, in some embodiments, sub-assembly 802 can be used to house battery 804. In some embodiments, sub-assembly 802 can be made from any suitable material, such as ceramic, plastic, and/or any other suitable material. In some embodiments, sub-assembly 802 can contain a slot, groove, and/or any other features to accommodate battery 804 and/or any other suitable component.

In some embodiments, battery 804 can be any suitable battery, such as battery 204 described in connection with FIG. 2. In some embodiments, as shown, battery 804 can include a pair of wires and/or a connector for connecting the battery to printed circuit board 808 for powering printed circuit board 808. For example, sub-assembly 802 can include a slot or any other suitable cut-out portion to accommodate a connector for battery 804 that has been placed within sub-assembly 802, where the connector connects battery 804 to printed circuit board 808.

As illustrated, mounting bracket 806 can be stacked upon sub-assembly 802 and battery 804 in some embodiments. In some embodiments, mounting bracket 806 can be used to secure a printed circuit board 808. As shown, in some embodiments, printed circuit board 808 can be secured to mounting bracket 806 using mounting hardware 810. In some embodiments, mounting bracket 806 can be made from ceramic, plastic, and/or any other suitable material, and contain any suitable features for mating with mounting hardware 810. For example, as shown in FIG. 8A, mounting hardware 810 can be any suitable screws which can be slotted through clearance holes in printed circuit board 808 and screw into mounting bracket 806. In some embodiments, mounting hardware 810 can be any other suitable mounting hardware for securing printed circuit board 808 to mounting bracket 806, such as a snapping board post.

In some embodiments, printed circuit board 808 can contain any suitable components, such as those described in connection with FIG. 2, and/or any other suitable components. For example, as shown, in some embodiments, printed circuit board 808 can contain components such as integrated circuits, analog components, a mating connector for battery 804, and/or any other suitable component(s). More specifically, in some embodiments, printed circuit board 808 can contain magnetometer 206, optical sensor 208, RF circuitry 210, debug interface 212, programming connector 214 and/or any other suitable component(s). As shown, antenna 812 can be connected to printed circuit board 808 in some embodiments. In some embodiments, antenna 812 can be a helical-shaped antenna that extends vertically from printed circuit board 808 towards the top portion of the vehicle sensor (e.g., a window). In some embodiments, antenna 812 can be implemented in the same manner as described in connection with antenna 216 of FIG. 2.

Turning to FIG. 8B, a cross-sectional view of an example vehicle sensor 850 including internal components 800 in accordance with some embodiments is shown. As illustrated, in some embodiments, vehicle sensor 850 can include a top housing part 852, a bottom housing part 854, a window 856, a gasket 858, and a spacer 860.

Top housing part 852, bottom housing part 854, and window 856 can together form a housing for hardware 800 in some embodiments.

Top housing part 852 can be made from any suitable materials in some embodiments. Likewise, bottom housing part 854 can be made from any suitable materials in some embodiments, and in some embodiments can be formed from the same material as top housing part 852. For example, top housing part 852 and/or bottom housing part 854 can be made from plastic, fiberglass, aluminum, etc.

As shown, in some embodiments, top housing part 852 can be wider than bottom housing part 854. As also shown, top housing part can be beveled, chamfered, and/or rounded on its top side, in some embodiments.

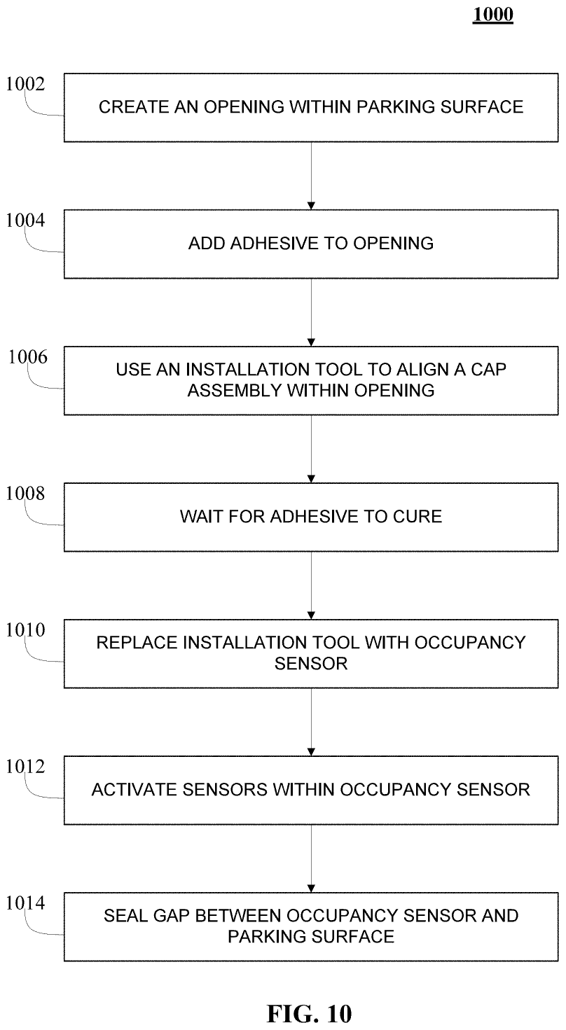

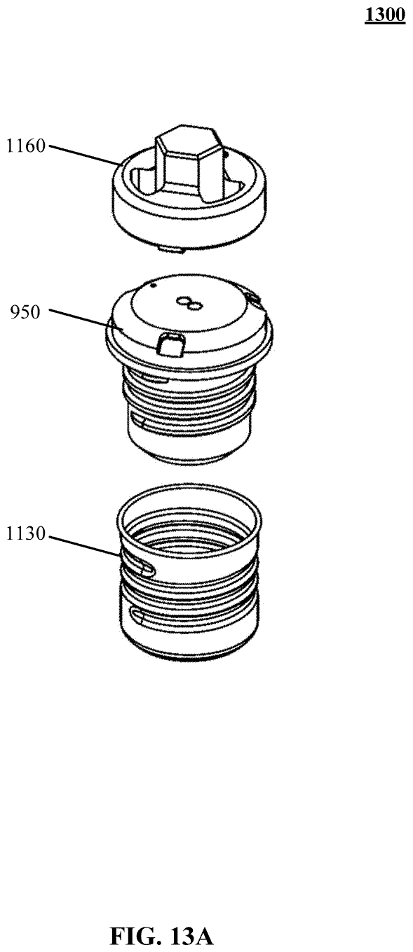

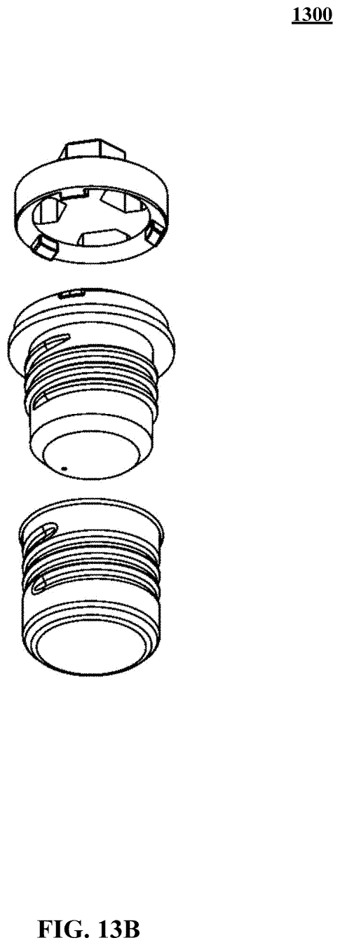

As shown, in some embodiments, bottom housing part 854 can have threads to enable the bottom part to be screwed into a corresponding threaded socket as described further below in connection with FIGS. 10, 13A, and 13B.

As illustrated, window 856 can be transparent to at least the wavelength of light used by an optical sensor on, or coupled to, circuit board 808. Window 856 can be made from any suitable material(s), such as glass, plastic, or plexiglass, in some embodiments. For example, in some embodiments, window 856 can be glass with any suitable coating such as an anti-reflective coating.

In some embodiments, gasket 858 can be made from silicone, rubber, and/or any suitable material. In some embodiments, gasket 858 can be attached to vehicle sensor 850 at the joint of top housing part 852 and bottom housing part 854, as shown in FIG. 8B, or placed in any suitable location.

In some embodiments, spacer 860 can be made from plastic, ceramic, and/or any other suitable material. Spacer 860 can have any suitable geometry in some embodiments. For example, as shown in FIG. 8B, spacer 860 can be a hollow cylinder placed around antenna 810 and can extend from printed circuit board 808 to any suitable height within vehicle sensor 850. In another example, as also shown in FIG. 8B, spacer 860 can be a hollow cylinder placed around antenna 810 that extends from printed circuit board 808 to the top portion of bottom housing part 854, while antenna 810 can extend to window 856.

Turning to FIG. 8C, a perspective-view illustration of vehicle sensor 850 is shown in accordance with some embodiments.

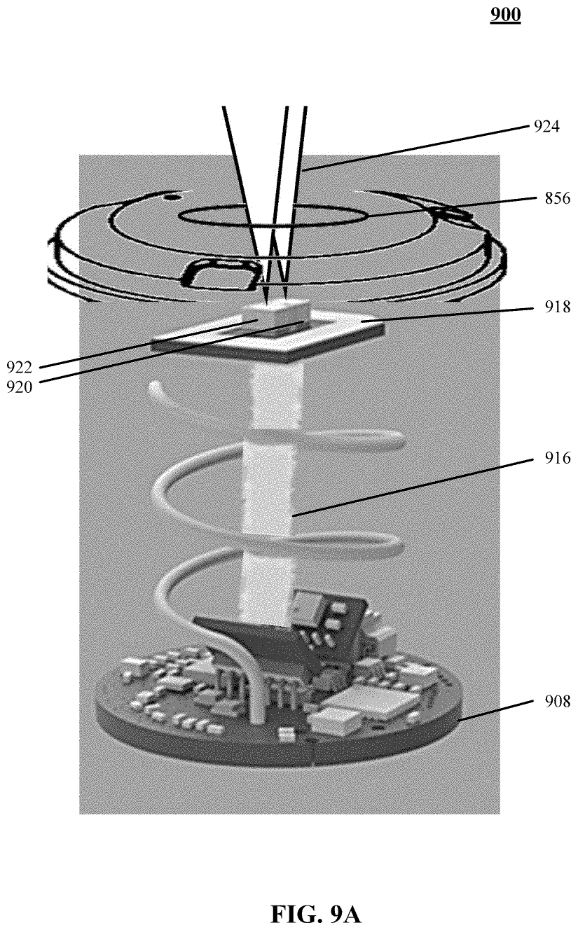

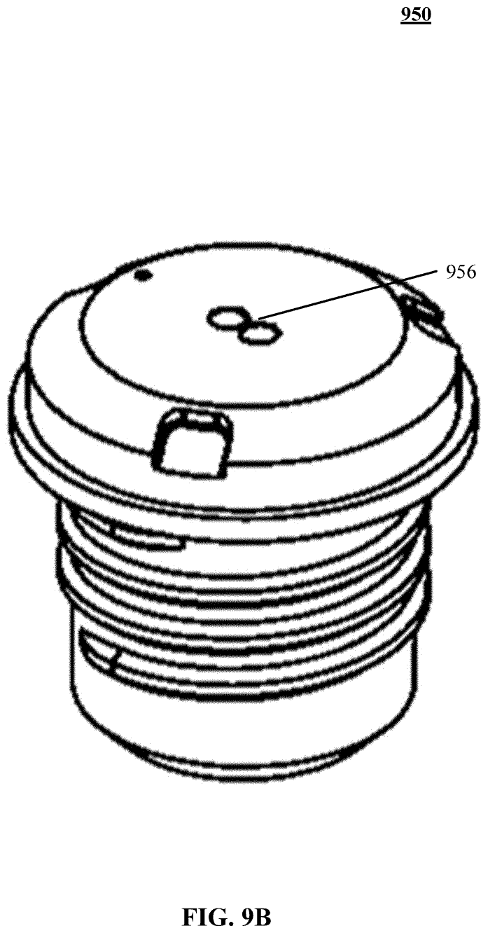

Turning to FIG. 9A, an alternative example 900 of hardware that can be used in an occupancy sensor in accordance with some embodiments is illustrated. As shown, in some embodiments, hardware 900 can be substantially similar to hardware 800 except that, instead of having an optical light source and detector mounted on printed circuit board 808 as in hardware 800, in hardware 900, an optical light source 920 and detector 922 are mounted on a separate circuit board 918 that can be mounted near window 856 and connected to printed circuit board 908 using a cable 916.

In some embodiments, printed circuit board 908 can contain electrical components that are the same or similar to the components described in connection with printed circuit board 808 of FIG. 8A. For example, the components of printed circuit board 908 can include the components shown in the schematic of FIG. 2, such as magnetometer(s) 206, RF circuitry 210, debug interface 212, programming connector 214 and/or any other suitable electronic components and integrated circuits.

As described above, in some embodiments, cable 916 can connect printed circuit board 908 and printed circuit board 918. In some embodiments, cable 916 can be any suitable ribbon cable, flex cable, and/or any other suitable cable with any suitable number of wires.

In some embodiments, optical light source 920 and detector 922 can be implemented in a manner described above in connection with optical sensor 208 in FIG. 2. In some embodiments, optical light source 920 and detector 922 can each have a characteristic field-of-view 924.

In some embodiments, field-of-view 924 can be a cone of any suitable size extending above the source 920 and/or detector 922 to any suitable height. For example, in some embodiments, the field-of-view 924 can be a cone of height between about 0.2 m and 1 m with a half-angle of 15°. In some embodiments, the field-of-view 924 associated with optical light source 920 and detector 922 can have the same geometry. In some embodiments, the field-of-view 924 associated with source 920 can be a different size than the field-of-view 924 associated with detector 922.

Turning to FIG. 9B, an example of vehicle sensor 956 in accordance with some embodiments is shown. As shown, in some embodiments, window 956 can be implemented with two individual windows. For example, referring back to FIG. 2, when optical sensor 208 is a time-of-flight sensor, microcontroller 202 can trigger or otherwise activate a time-of-flight measurement by using a laser as an emitter to transmit photons through one of the individual windows 956 to a target (e.g., a parked vehicle) and an avalanche diode as a sensor that detects or otherwise measures the time the photons have taken to travel from the laser to the object and back to the sensor through one of the individual windows 956. In some embodiments, window 956 can be used in combination with hardware 900, and/or any other suitable hardware. In some embodiments, window 956 can be larger than field-of-view 924, and/or any suitable size.

Turning to FIG. 10, an example 1000 of a process for installing a vehicle sensor and socket in accordance with some embodiments is shown.

In some embodiments, process 1000 can be used in locations where a snowplow, street sweeper, street maintenance vehicle, and/or any other suitable vehicle are routinely used. Note that installation in a manner described by process 1000 can, in some embodiments, allow operation of vehicle sensor 850 and/or 950 concurrent with the regular operation of a snowplow, street sweeper, and/or any other suitable vehicle. For example, in some embodiments, installation of a vehicle sensor using process 1000 can prevent damage to both the vehicle sensor 850 and/or 950 and a snowplow, street sweeper, and/or any other suitable vehicle.

Process 1000 can begin at 1002 by a technician creating an opening within parking surface 100. In some embodiments, the opening can be any size or shape and be created by a drill, jackhammer, and/or any suitable tool to remove concrete, asphalt, and/or any other suitable parking lot material. For example, an opening of about 2 inches in diameter can be created by using a drill or any other suitable battery-operated tool having a corresponding drill bit for cutting a suitable opening. In some embodiments, the opening can be sized to fit at least vehicle sensor 850 and/or 950. For example, the opening can have a depth that is at least equal to or greater than the height of vehicle sensor 850 and/or 950 in some embodiments.

Next, at 1004, a technician can add adhesive to the opening created at 1002. In some embodiments, the adhesive can be an epoxy, multi-part epoxy, resin, glue, and/or any other suitable material. In some embodiments, a technician can add adhesive to the opening using any suitable mechanism.

Then, at 1006, a technician can align a socket into the opening. In some embodiments, a technician can locate the final vertical position of the socket using features of an installation tool, as described further below in connection with FIG. 11.

Next, at 1008, a technician can wait for the adhesive added at 1004 to cure. In some embodiments, the installation tool can remain in contact with the socket during 1008.

After, at 1010, a technician can thread the vehicle sensor 850 and/or 950 into the socket. In some embodiments, any suitable accessories can be used to aid the technician at 1010. For example, as discussed below in connection with FIG. 13, an installation handle can mate with vehicle sensor 850 and/or 950 in some embodiments. In some embodiments, vehicle sensor 850 and/or 950 can be level with the parking lot surface. Alternatively, in some embodiments, vehicle sensor 850 and/or 950 can be below the level of the parking lot surface.

Next, at 1012, a technician can initialize vehicle sensor 850 and/or 950. In some embodiments, initializing the vehicle sensor can include linking vehicle sensor 850 and/or 950 to gateway device 106, wherein the link can be implemented in the same manner as described in connection with FIG. 1B. In some embodiments, initializing the vehicle sensor can include calibrating vehicle sensor 850 and/or 950 using any suitable mechanism. For example, in some embodiments, gateway device 106 can direct vehicle sensor 850 and/or 950 to perform a calibration routine. In some embodiments, initializing the vehicle sensor can include measuring a local background magnetic field using magnetometer(s) in vehicle sensor 850 and/or 950. In some embodiments, vehicle sensor 850 and/or 950 can locally store a calibration measurement in non-volatile memory. In some embodiments, vehicle sensor 850 and/or 950 can transmit a calibration measurement to gateway device 106 as part of a calibration routine.

Finally, at 1014, a technician can seal vehicle sensor into the parking lot. In some embodiments, a technician can use rubber, caulk, silicon and/or any other suitable material to create a seal. In some embodiments, a technician can back-fill a gap which can remain between vehicle sensor 850 and/or 950 and the parking lot surface. For example, a technician can seal a top perimeter region between the vehicle sensor, such as vehicle sensor 850 and/or 950, and the parking lot surface with a bead of low viscosity rubber.

Turning to FIG. 11, an illustration 1100 of hardware that can be used to install a vehicle sensor in accordance with some embodiments is shown. For example, illustration 1100 shows an installation tool 1110, an alignment spacer 1120, and a socket 1130.

In some embodiments, installation tool 1110 can be made from plastic, rubber, aluminum, and/or any suitable material. In some embodiments, installation tool 1110 can be used in a similar manner as described in connection with 1006 in FIG. 10 above. In some embodiments, installation tool 1110 can include an upper half 1112 and a lower half 1118. In some embodiments, upper half 1112 can be shaped to form a handle, as shown in FIG. 11. In some embodiments, lower half 1118 can include threads which are complimentary to threads found in socket 1130.

In some embodiments, installation tool 1110 can include a flange 1116 between upper half 1112 and lower half 1118. In some embodiments, flange 1116 can be wider than lower half 1118. In some embodiments, installation tool 1110 can include any suitable features such as openings 1114 placed in any suitable location. For example, openings 1114 can be placed, in some embodiments, such that excess adhesive (e.g., epoxy) can escape when installation tool 1110 is used in a similar manner as described in 1006 and 1008 of process 1000. In some embodiments, installation tool 1110 can include any other suitable features.

In some embodiments, alignment spacer 1120 can be made from plastic, rubber, aluminum, and/or any suitable material. In some embodiments, alignment spacer 1120 can be an annulus with any inner diameter and any outer diameter. In some embodiments, alignment spacer 1120 can be any suitable height. For example, in some embodiments, alignment spacer 1120 can be a height which allows fine adjustment of socket 1130 to a desired vertical position inside the opening created at 1002 of FIG. 10. In some embodiments, alignment spacer 1120 can include any suitable features.

In some embodiments, socket 1130 can be made from plastic, rubber, aluminum, and/or any suitable material. In some embodiments, socket 1130 can be sized to thread around vehicle sensor 850 and/or 950. For example, in some embodiments, socket 1130 can have a threaded middle section which is complimentary to the threading in bottom part 854 of vehicle sensor 850 and/or 950. In some embodiments, socket 1130 can have a rounded edge and/or any other suitable edge finish. In some embodiments, socket 1130 can create a seal with vehicle sensor 850 and/or 950. For example, in some embodiments, gasket 858 can make contact with socket 1130 to create a seal with vehicle sensor 850 and/or 950.

Turning to FIG. 12, an illustration 1200 of a vehicle sensor installation in accordance with some embodiments is shown. In some embodiments, installation tool 1110, socket 1130, adhesive 1140 and opening 1150 are arranged as described in connection with process 1000 in FIG. 10. In some embodiments, socket 1130 can be aligned vertically in opening 1150 based on the shape of installation tool 1110. In some embodiments, vertical alignment of socket 1130 can be selected to align vehicle sensor 850 and/or 950 below the top of opening 1150 when threading vehicle sensor 850 and/or 950 into socket 1130.

Turning to FIG. 13A, an example 1300 of sensor installation hardware in accordance with some embodiments is shown. As illustrated, this hardware can include socket 1130, vehicle sensor 850 and/or 950, and installation handle 1160 in some embodiments. In some embodiments, vehicle sensor 850 and/or 950 can thread into socket 1130. In some embodiments, installation handle 1160 can be shaped to fit any grooves and/or any suitable features on vehicle sensor 850 and/or 950. In some embodiments, installation handle 1160 can be made from plastic, rubber, aluminum, and/or any suitable material.

FIG. 13B illustrates a rotated view of illustration 1300 in accordance with some embodiments.

Turning to FIGS. 14A, 14B and 14C, examples of a vehicle sensor installed into a parking lot 1410 in accordance with some embodiments are shown. Note that, in some embodiments, a completed sensor installation can result in vehicle sensor 850 and/or 950 fully seated beneath the top surface of parking surface 1410. In some embodiments, vehicle sensors installed in this manner can provide a solution for monitoring parking surfaces which are maintained using snowplows, street sweepers, and/or any other suitable machinery which contacts the road surface.

Turning to FIG. 14A, an example 1401 of vehicle sensor 950 installed into a parking lot 1410 in accordance with some embodiments is shown. Additionally or alternatively, in some embodiments, vehicle sensor 850 (not shown) can be installed in parking lot 1410. In some embodiments, as illustrated, the vehicle sensor is installed into parking lot 1410 using the threads on the exterior of vehicle sensor and complimentary socket 1130, as described in connection with FIGS. 8A and 11.

Turning to FIG. 14B, an example 1402 of a vehicle sensor 1450 installed into a parking lot 1410 in accordance with some embodiments is shown. Vehicle sensor 1450 can be implemented as described above for vehicle sensor 850 and/or 950, but instead of having threads on its outside, it can have one or more protrusions 1423 (e.g., like in a bayonet connector) that engage with one or more slots in a corresponding socket. For example, as shown in FIG. 14B, in some embodiments, a socket 1420 can have one or more L-shaped slots 1421 at the top of the socket and a spring 1422 at the bottom of the socket. When sensor 1450 is placed in the socket, the sensor can compress the spring and the one or more protrusions can enter the one or more slots. The sensor can then be rotated and released so that the one or more protrusions are captive at the distal end of the one or more slots under the pressure of the spring. While a particular shape of slot is illustrated in FIG. 14B, any suitably shaped and sized slot can be used in some embodiments. For example, the slots can have any suitable depth along the vertical dimension of the socket and any suitable width around the circumference of the socket (which can be measure in units of distance or length, or in units of degrees or radians). In some embodiments, rather than using a slot, a similarly shaped groove can be used on the interior of the socket. In some embodiments, any suitably shaped and sized protrusions can be used in some embodiments.

Turning to FIG. 14C, an example 1403 of a vehicle sensor 1475 installed into a parking lot 1410 in accordance with some embodiments is shown. Vehicle sensor 1475 can be implemented as described above for vehicle sensor 850 and/or 950, but instead of having threads on its outside, it can have a smooth exterior surface and can use an actuator 1440 to move the sensor out of a socket 1430 it is in when necessary for servicing or replacement. A suitable actuator 1440 can be used in some embodiments. For example, actuator 1440 can be a linear actuator that pushes sensor 1475 up and out of socket 1430. In some embodiments, actuator 1440 can be any size, shape, and use any suitable technology to create motion. For example, in some embodiments, actuator 1440 can include a piezoelectric motor. In some embodiments, actuator 1440 can extend to any suitable height. In some embodiments, actuator 1440 can have error-correction feedback (servo). In some embodiments, actuator 1440 can be controlled by the microcontroller in response to any suitable external signal received from the gateway and/or from any other suitable device (such as a mobile device operated by a technician).

In some embodiments, at least some of the above-described blocks of the process of FIG. 3 and the process of FIG. 7 can be executed or performed in any order or sequence not limited to the order and sequence shown in and described in connection with the figures. Also, some of the above blocks of FIG. 3 and/or of FIG. 7 can be executed or performed substantially simultaneously where appropriate or in parallel to reduce latency and processing times. Additionally or alternatively, some of the above described blocks of the process of FIG. 3 and/or of the process of FIG. 7 can be omitted.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Accordingly, wireless occupancy sensors and methods for using the same are provided.

Although the invention has been described and illustrated in the foregoing illustrative embodiments, it is understood that the present disclosure has been made only by way of example, and that numerous changes in the details of implementation of the invention can be made without departing from the spirit and scope of the invention. Features of the disclosed embodiments can be combined and rearranged in various ways.

What is claimed is:

1. An occupancy sensor comprising:
a housing that includes a window positioned at a top portion of the housing;
a battery at a lower portion of the housing;
a first magnetometer that detects changes in a magnetic field when a vehicle moves over the first magnetometer;
an optical sensor that detects one or more objects in a field of view of the optical sensor through the window;
a transmitter for transmitting sensor data to a gateway device, and
a processor that controls the first magnetometer, the optical sensor, and the transmitter.

2. The occupancy sensor of claim 1, wherein the housing includes a first set of exterior threads on a body portion of the housing that match a second set of interior threads on a socket configured to be positioned within an opening of a surface.

3. The occupancy sensor of claim 1, wherein the first magnetometer is a low-power magnetometer, and wherein the optical sensor is woken in response to the first magnetometer detecting a change in a magnetic field.

4. The occupancy sensor of claim 1, further comprising a second magnetometer.

5. The occupancy sensor of claim 1, wherein the optical sensor is an infrared sensor.

6. The occupancy sensor of claim 1, wherein the optical sensor is a time-of-flight sensor.

7. The occupancy sensor of claim 6, wherein the transmitter and the processor are mounted on a first printed circuit board and the time-of-flight sensor is mounted on a second printed circuit board that is separate from the first printed circuit board and wherein the second printed circuit board mounted at the top portion of the housing.

8. The occupancy sensor of claim 7, further comprising a cable that connects the second printed circuit board to the first printed circuit board.

9. The occupancy sensor of claim 1, wherein the optical sensor is a pulse doppler radar sensor.

10. The occupancy sensor of claim 1, wherein the optical sensor is an infrared pulse doppler radar sensor.

11. The occupancy sensor of claim 1, wherein the transmitter is a wireless transmitter and further comprising an antenna coupled to an output of the transmitter.

12. The occupancy sensor of claim 11, wherein the antenna is a helical-shaped antenna that extends vertically through a body portion of the housing.

13. The occupancy sensor of claim 11, wherein the transmitter is configured to transmit sensor data over a 915 MHz radio protocol to a gateway device.

14. The occupancy sensor of claim 1, further comprising a humidity sensor to indicate whether water has leaked into the occupancy sensor.

15. The occupancy sensor of claim 1, further comprising a feedback indicator.

16. The occupancy sensor of claim 15, wherein the feedback indicator is a light emitting diode.

17. The occupancy sensor of claim 1, wherein the housing includes at least one protrusion on an exterior surface of a body portion of the housing that is configured to engage with a socket under the pressure of a spring.

18. The occupancy sensor of claim 1, further comprising an actuator that is configured to change a position of the occupancy sensor within a socket.

19. The occupancy sensor of claim 1, further comprising a gasket configured to seal an interior space of a socket when the occupancy sensor is fully inserted into the socket.
